(19) United States
(12) Patent Application Publication
(10) Pub. No.: US 2025/0120210 A1
(43) Pub. Date: Apr. 10, 2025

(54) SOLID STATE IMAGING DEVICE AND ELECTRONIC APPARATUS

(71) Applicant: SONY SEMICONDUCTOR SOLUTIONS CORPORATION, KANAGAWA (JP)

(72) Inventors: TAKUYA ITO, KANAGAWA (JP); TAKAYUKI ENOMOTO, KANAGAWA (JP); MASAKI OKAMOTO, KANAGAWA (JP); NOBUYA NAKAZAKI, KANAGAWA (JP)

(21) Appl. No.: 18/834,411

(22) PCT Filed: Jan. 27, 2023
(86) PCT No.: PCT/JP2023/002731

§ 371 Date: Jul. 30, 2024

(30) Foreign Application Priority Data
Feb. 8, 2022 (JP) 2022-018197

(51) Int. Cl. H10F 39/00; H10F 39/18

(52) U.S. Cl. CPC H10F 39/807; H10F 39/014; H10F 39/182

(57) ABSTRACT

A solid state imaging device according to an embodiment includes: a pixel separation unit that partitions a first surface of a semiconductor substrate into a plurality of first regions arrayed in a matrix shape; an in-pixel separation unit that divides each of the first regions into at least two second regions; an etching stopper region disposed in at least a partial space between the pixel separation unit and the in-pixel separation unit in a plane parallel to the first surface and in a direction perpendicular to a direction in which the at least two second regions divided by the in-pixel separation unit are arrayed; a photoelectric conversion unit disposed in each of the second regions; and a transfer transistor connected to each of the photoelectric conversion units.

### FIELD

The present disclosure relates to a solid state imaging device and an electronic apparatus.

### BACKGROUND

In recent years, so-called image plane phase difference autofocus, which detects a phase difference using a pair of adjacent phase difference detection pixels, has been attracting attention as technology for implementing an autofocus function of an imaging device.

### CITATION LIST

### Patent Literature

Patent Literature 1: JP 2018-201015 A

### SUMMARY

### Technical Problem

However, in a solid state imaging device adopting image plane phase difference autofocus, a plurality of light receiving units formed in a substrate is separated by light shielding units embedded in trench portions formed from a back surface side of the substrate. For this reason, light incident from an oblique direction on the back surface side of the substrate, which is serving as a light irradiation surface, is blocked by the light shielding units, and there is a possibility that the light receiving sensitivity may decrease.

Therefore, the present disclosure proposes a solid state imaging device and an electronic apparatus capable of suppressing a decrease in the light receiving sensitivity.

### Solution to Problem

To solve the above-described problem, a solid state imaging device according to one aspect of the present disclosure includes: a pixel separation unit that partitions a first surface of a semiconductor substrate into a plurality of first regions arrayed in a matrix shape; an in-pixel separation unit that divides each of the first regions into at least two second regions; an etching stopper region disposed in at least a partial space between the pixel separation unit and the in-pixel separation unit in a plane parallel to the first surface and in a direction perpendicular to a direction in which the at least two second regions divided by the in-pixel separation unit are arrayed; a photoelectric conversion unit disposed in each of the second regions; and a transfer transistor connected to each of the photoelectric conversion units.

A solid-state imaging device according to another aspect of the present disclosure includes: a pixel separation unit that partitions a first surface of a semiconductor substrate into a plurality of first regions arrayed in a matrix shape; an in-pixel separation unit that divides each of the first regions into at least two second regions, and that includes an overflow path region for allowing charge accumulated in one of the at least two second regions to flow into at least another second region; a photoelectric conversion unit disposed in each of the second regions; and a transfer transistor connected to each of the photoelectric conversion units. In the solid-state imaging device, at least a part of the in-pixel separation unit has an impurity concentration profile adjusted such that a potential barrier becomes higher toward a center of the in-pixel separation unit and that the potential barrier becomes higher as a distance from the overflow path increases in a plane parallel to the first surface.

### BRIEF DESCRIPTION OF DRAWINGS

FIG. 1 is a block diagram illustrating a schematic configuration example of an electronic apparatus mounted with a solid state imaging device according to a first embodiment of the present disclosure.

FIG. 2 is a block diagram illustrating a schematic configuration example of a CMOS solid state imaging device according to the first embodiment of the present disclosure.

FIG. 3 is a circuit diagram illustrating a schematic configuration example of a pixel according to the first embodiment of the present disclosure.

FIG. 4 is a diagram illustrating a stacked structure example of an image sensor according to the first embodiment of the present disclosure.

FIG. 5 is a cross-sectional view illustrating a basic cross-sectional structure example of a pixel according to the first embodiment of the present disclosure.

FIG. 6 is a vertical cross-sectional view illustrating a schematic structure example of an image plane phase difference pixel according to the first embodiment of the present disclosure.

FIG. 7 is a vertical cross-sectional view illustrating a schematic structure example of the image plane phase difference pixel according to the first embodiment of the present disclosure when cut along a plane different from that in FIG. 6.

FIG. 8 is a horizontal cross-sectional view illustrating a schematic structure example of the image plane phase difference pixel according to the first embodiment of the present disclosure.

FIG. 9 is a horizontal cross-sectional view illustrating a schematic structure example of the image plane phase difference pixel according to the first embodiment of the present disclosure when cut along a plane different from that in FIG. 8.

FIG. 10 is a process cross-sectional view for explaining a manufacturing method of the solid state imaging device according to the first embodiment of the present disclosure (part 1).

FIG. 11 is a process cross-sectional view for explaining the manufacturing method of the solid state imaging device according to the first embodiment of the present disclosure (part 2).

FIG. 12 is a process cross-sectional view for explaining the manufacturing method of the solid state imaging device according to the first embodiment of the present disclosure (part 3).

FIG. 13 is a process cross-sectional view for explaining the manufacturing method of the solid state imaging device according to the first embodiment of the present disclosure (part 4).

FIG. 14 is a process cross-sectional view for explaining the manufacturing method of the solid state imaging device according to the first embodiment of the present disclosure (part 5).

FIG. 15 is a process cross-sectional view focusing on a manufacturing process of a pixel separation unit in the manufacturing method of the solid state imaging device according to the first embodiment of the present disclosure (part 1).

FIG. 16 is a process cross-sectional view focusing on the manufacturing process of the pixel separation unit in the manufacturing method of the solid state imaging device according to the first embodiment of the present disclosure (part 2).

FIG. 17 is a process cross-sectional view focusing on the manufacturing process of the pixel separation unit in the manufacturing method of the solid state imaging device according to the first embodiment of the present disclosure (part 3).

FIG. 18 is a process cross-sectional view focusing on the manufacturing process of the pixel separation unit in the manufacturing method of the solid state imaging device according to the first embodiment of the present disclosure (part 4).

FIG. 19 is a process cross-sectional view focusing on the manufacturing process of the pixel separation unit in the manufacturing method of the solid state imaging device according to the first embodiment of the present disclosure (part 5).

FIG. 20 is a process cross-sectional view focusing on the manufacturing process of the pixel separation unit in the manufacturing method of the solid state imaging device according to the first embodiment of the present disclosure (part 6).

FIG. 21 is a vertical cross-sectional view illustrating a schematic structure example of an image plane phase difference pixel during manufacturing according to a first modification of the first embodiment of the present disclosure.

FIG. 22 is a vertical cross-sectional view illustrating a schematic structure example of another image plane phase difference pixel during manufacturing according to the first modification of the first embodiment of the present disclosure.

FIG. 23 is a vertical cross-sectional view illustrating a schematic structure example of an image plane phase difference pixel according to a second modification of the first embodiment of the present disclosure.

FIG. 24 is a vertical cross-sectional view illustrating a schematic structure example of an image plane phase difference pixel according to a third modification of the first embodiment of the present disclosure.

FIG. 25 is a vertical cross-sectional view illustrating a schematic structure example of an image plane phase difference pixel according to a fourth modification of the first embodiment of the present disclosure.

FIG. 26 is a vertical cross-sectional view illustrating a schematic structure example of an image plane phase difference pixel according to a fifth modification of the first embodiment of the present disclosure.

FIG. 27 is a vertical cross-sectional view illustrating a schematic structure example of an image plane phase difference pixel according to a sixth modification of the first embodiment of the present disclosure.

FIG. 28 is a graph illustrating wavelength dependency of a refractive index n and band gap energy k of silicon (Si).

FIG. 29 is a graph illustrating wavelength dependency of the refractive index n and the band gap energy k of gallium arsenide (GaAs) which is a candidate for a material used for an in-pixel separation unit in a second embodiment of the present disclosure.

FIG. 30 is a graph illustrating wavelength dependency of the refractive index n and the band gap energy k of gallium phosphide (GaP) which is a candidate for a material used for the in-pixel separation unit in the second embodiment of the present disclosure.

FIG. 31 is a graph illustrating wavelength dependency of the refractive index n and the band gap energy k of aluminum arsenide (AlAs) which is a candidate for a material used for the in-pixel separation unit in the second embodiment of the present disclosure.

FIG. 32 is a graph illustrating wavelength dependency of the refractive index n and the band gap energy k of aluminum antimonide (AlSb) which is a candidate for a material used for the in-pixel separation unit in the second embodiment of the present disclosure.

FIG. 33 is a graph illustrating wavelength dependency of the refractive index n and the band gap energy k of indium phosphide (InP) which is a candidate for a material used for the in-pixel separation unit in the second embodiment of the present disclosure.

FIG. 34 is a graph illustrating wavelength dependency of the refractive index n and the band gap energy k of hexagonal silicon carbide (4H-SiC) which is a candidate for a material used for the in-pixel separation unit in the second embodiment of the present disclosure.

FIG. 35 is a graph illustrating wavelength dependency of the refractive index n of diamond which is a candidate for a material used for the in-pixel separation unit in the second embodiment of the present disclosure.

FIG. 36 is a graph illustrating wavelength dependency of the refractive index n and the band gap energy k of DLC which is a candidate for a material used for the in-pixel separation unit in the second embodiment of the present disclosure.

FIG. 37 is a graph illustrating wavelength dependency of a refractive index n and a band gap energy k of zinc selenide (ZnSe) which is a candidate for a material used for the in-pixel separation unit in the second embodiment of the present disclosure.

FIG. 38 is a top view illustrating a planar structure example of an image plane phase difference pixel according to a third embodiment of the present disclosure.

FIG. 39 is a vertical cross-sectional view illustrating a structure example of a cross section taken along line E-E in FIG. 38.

FIG. 40 is a vertical cross-sectional view illustrating a structure example of a cross section taken along line F-F in FIG. 38.

FIG. 41 is a process cross-sectional view illustrating a manufacturing method of a solid state imaging device according to a third embodiment of the present disclosure (part 1).

FIG. 42 is a process cross-sectional view illustrating the manufacturing method of the solid state imaging device according to the third embodiment of the present disclosure (part 2).

FIG. 43 is a process cross-sectional view illustrating the manufacturing method of the solid state imaging device according to the third embodiment of the present disclosure (part 3).

FIG. 44 is a process cross-sectional view illustrating the manufacturing method of the solid state imaging device according to the third embodiment of the present disclosure (part 4).

FIG. 45 is a process cross-sectional view illustrating the manufacturing method of the solid state imaging device according to the third embodiment of the present disclosure (part 5).

FIG. 46 is a process cross-sectional view illustrating the manufacturing method of the solid state imaging device according to the third embodiment of the present disclosure (part 6).

FIG. 47 is a process cross-sectional view illustrating the manufacturing method of the solid state imaging device according to the third embodiment of the present disclosure (part 7).

FIG. 48 is a vertical cross-sectional view illustrating a cross-sectional structure example of an image plane phase difference pixel according to a first modification of the third embodiment of the present disclosure.

FIG. 49 is a vertical cross-sectional view illustrating a cross-sectional structure example of an image plane phase difference pixel according to a second modification of the third embodiment of the present disclosure.

FIG. 50 is a vertical cross-sectional view illustrating a cross-sectional structure example of an image plane phase difference pixel according to a third modification of the third embodiment of the present disclosure.

FIG. 51 is a vertical cross-sectional view illustrating a cross-sectional structure example of an image plane phase difference pixel according to a fourth modification of the third embodiment of the present disclosure.

FIG. 52 is a vertical cross-sectional view illustrating a cross-sectional structure example of an image plane phase difference pixel according to a fifth modification of the third embodiment of the present disclosure.

FIG. 53 is a vertical cross-sectional view illustrating a cross-sectional structure example of an image plane phase difference pixel according to a sixth modification of the third embodiment of the present disclosure.

FIG. 54 is a vertical cross-sectional view illustrating a cross-sectional structure example of an image plane phase difference pixel according to a seventh modification of the third embodiment of the present disclosure.

FIG. 55 is a vertical cross-sectional view illustrating a cross-sectional structure example of an image plane phase difference pixel according to an eighth modification of the third embodiment of the present disclosure.

FIG. 56 is a block diagram illustrating an example of a schematic functional configuration of a smartphone.

FIG. 57 is a block diagram depicting an example of schematic configuration of a vehicle control system.

FIG. 58 is a diagram of assistance in explaining an example of installation positions of an outside-vehicle information detecting section and an imaging section.

FIG. 59 is a view depicting an example of a schematic configuration of an endoscopic surgery system.

FIG. 60 is a block diagram depicting an example of a functional configuration of a camera head and a camera control unit (CCU).

### DESCRIPTION OF EMBODIMENTS

Hereinafter, an embodiment of the present disclosure will be described in detail on the basis of the drawings. Note that in each of the following embodiments, the same parts are denoted by the same symbols, and redundant description will be omitted.

The present disclosure will be described in the following order of items.
1. First Embodiment
1.1 Configuration Example of Electronic Apparatus (Imaging Device)
1.2 Configuration Example of Solid State Imaging Device
1.3 Configuration Example of Pixel
1.4 Example of Basic Function of Pixel
1.5 Stacked Structure Example of Solid State Imaging Device
1.6 Basic Structure Example of Pixels
1.7 Schematic Cross-Sectional Structure Example of Image Plane Phase Difference Pixel
1.8 Problem in Image Plane Phase Difference Pixel Structure
1.9 Cross-Sectional Structure Example of Image Plane Phase Difference Pixel
1.10 Manufacturing Method
1.11 Summary
1.12 Modifications
1.12.1 First Modification
1.12.2 Second Modification
1.12.3 Third Modification
1.12.4 Fourth Modification
1.12.5 Fifth Modification
1.12.6 Sixth Modification
2. Second Embodiment
2.1 First Example
2.2 Second Example
2.3 Third Example
2.4 Fourth Example
2.5 Fifth Example
2.6 Sixth Example
2.7 Seventh Example
2.8 Eighth Example
2.9 Ninth Example
2.10 Other Examples
2.11 Summary
3. Third Embodiment
3.1 Cross-Sectional Structure Example of Image Plane Phase Difference Pixel
3.2 Manufacturing Method
3.3 Modification of Image Plane Phase Difference Pixel Structure
3.3.1 First Modification
3.3.2 Second Modification
3.3.3 Third Modification
3.3.4 Fourth Modification
3.3.5 Fifth Modification
3.3.6 Sixth Modification
3.3.7 Seventh Modification
3.3.8 Eighth Modification
3.4 Summary
4. Application Example to Smartphone
5. Application Example to Mobile Body
6. Application Example to Endoscopic Surgery System

### 1. First Embodiment

First, a first embodiment of the present disclosure will be described in detail with reference to the drawings. Note that, in the present embodiment, a case where the technology according to the present embodiment is applied to a complementary metal-oxide-semiconductor (CMOS) type solid state imaging device (hereinafter, also referred to as an image sensor) will be described as an example; however, it is not limited thereto. For example, the technology according to the present embodiment can be applied to various sensors including a photoelectric conversion element, such as a charge coupled device (CCD) type solid state imaging device, a time of flight (ToF) sensor, or an event-based vision sensor (EVS).

### 1.1 Configuration Example of Electronic Apparatus (Imaging Device)

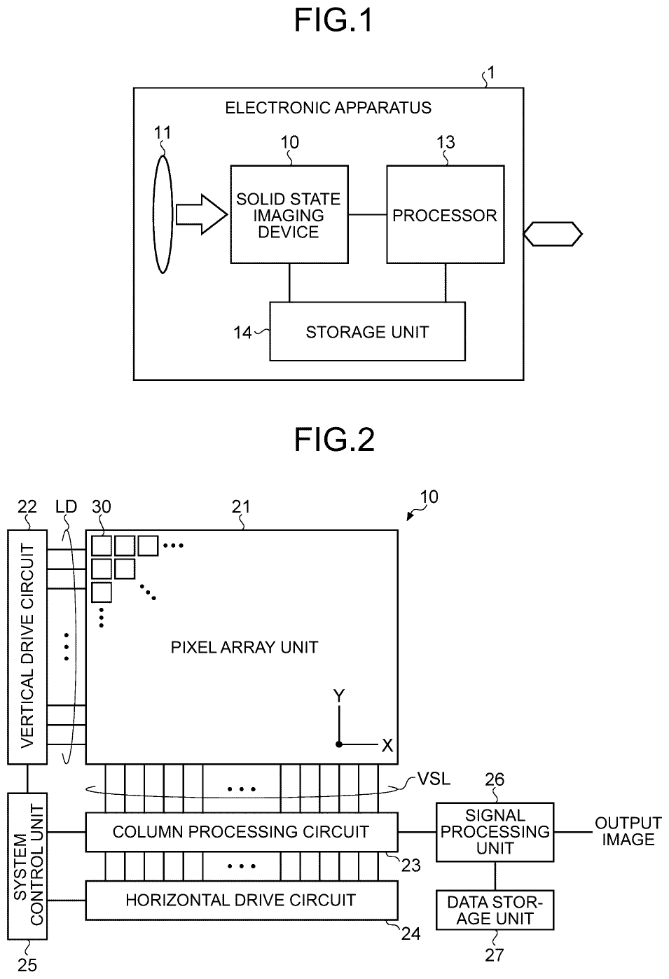

FIG. 1 is a block diagram illustrating a schematic configuration example of an electronic apparatus (imaging device) mounted with a solid state imaging device according to a first embodiment. As illustrated in FIG. 1, an imaging device 1 includes, for example, an imaging lens 11, a solid state imaging device 10, a storage unit 14, and a processor 13.

The imaging lens 11 is an example of an optical system that condenses incident light and forms an image thereof on a light receiving surface of the solid state imaging device 10. The light receiving surface may be a surface on which photoelectric conversion elements are arrayed in the solid state imaging device 10. The solid state imaging device 10 photoelectrically converts incident light to generate image data. The solid state imaging device 10 further executes predetermined signal processing such as noise removal and white balance adjustment on the image data that has been generated. The storage unit 14 includes, for example, a flash memory, a dynamic random access memory (DRAM), a static random access memory (SRAM), or the like and records image data or the like input from the solid state imaging device 10.

The processor 13 includes, for example, a central processing unit (CPU) or the like and may include an application processor that executes an operating system, various types of application software, or the like, a graphics processing unit (GPU), a baseband processor, or the like. The processor 13 executes various types of processing as necessary on the image data input from the solid state imaging device 10, image data read from the storage unit 14, and the like, executes display to a user, and transmits the image data to the outside via a predetermined network.

### 1.2 Configuration Example of Solid State Imaging Device

FIG. 2 is a block diagram illustrating a schematic configuration example of a CMOS solid state imaging device according to the first embodiment. Incidentally, the CMOS solid state imaging device is an image sensor created by applying or partially using a CMOS process. For example, the solid state imaging device 10 according to the present embodiment includes a back-illuminated image sensor.

The solid state imaging device 10 according to the present embodiment has, for example, a stack structure in which a light receiving chip 41 (substrate) on which a pixel array unit 21 is disposed and a circuit chip 42 (substrate) on which peripheral circuits are disposed are stacked (see, for example, FIG. 4). The peripheral circuits may include, for example, a vertical drive circuit 22, a column processing circuit 23, a horizontal drive circuit 24, and a system control unit 25.

The solid state imaging device 10 further includes a signal processing unit 26 and a data storage unit 27. The signal processing unit 26 and the data storage unit 27 may be provided on the same semiconductor chip as the peripheral circuits or may be provided on another semiconductor chip.

The pixel array unit 21 has a configuration in which pixels 30 each having a photoelectric conversion element that generates and accumulates charge depending on the amount of received light are arranged in a row direction and a column direction, namely, in a two-dimensional lattice shape in a matrix shape. Incidentally, the row direction refers to an array direction of pixels in a pixel row (lateral direction in the drawing), and the column direction refers to an array direction of pixels in a pixel column (vertical direction in the drawing). A specific circuit configuration and pixel structure of a pixel 30 will be described later in detail.

In the pixel array unit 21, pixel drive lines LD are wired along the row direction for each pixel row, and vertical signal lines VSL are wired along the column direction for each pixel column for to the matrix-shaped pixel array. The pixel drive lines LD transmit a drive signal for driving when a signal is read from a pixel. In FIG. 2, the pixel drive lines LD are illustrated as being wired line by line; however, it is not limited to wiring line by line. One end of a pixel drive line LD is connected to an output terminal corresponding to one of the rows of the vertical drive circuit 22.

The vertical drive circuit 22 includes a shift register, an address decoder, and the like and drives the pixels of the pixel array unit 21 simultaneously for all the pixels or row by row. That is, the vertical drive circuit 22, together with the system control unit 25 that controls the vertical drive circuit 22, constitutes a driving unit that controls the operation of each of the pixels of the pixel array unit 21. Although a specific configuration of the vertical drive circuit 22 is not illustrated, vertical drive circuits generally include two scanning systems of a read scanning system and a sweep scanning system.

In order to read signals from the pixels 30, the read scanning system sequentially and selectively and scans the pixels 30 of the pixel array unit 21 row by row. The signals read from the pixels 30 are analog signals. The sweep scanning system performs sweep scanning on a reading row, on which read scanning is to be performed by the read scanning system, earlier than the read scanning by an exposure time.

By the sweep scanning by the sweep scanning system, unnecessary charge is swept out from photoelectric conversion elements of pixels 30 of a reading row, whereby the photoelectric conversion elements are reset. With the sweep scanning system sweeping out (resetting) unnecessary charge, a so-called electronic shutter operation is performed. Incidentally, the electronic shutter operation refers to an operation of discarding charge of the photoelectric conversion elements and newly starting exposure (starting accumulation of charge).

A signal read by the read operation by the read scanning system corresponds to the amount of light received after the immediately preceding read operation or electronic shutter operation. Moreover, a period from the read timing by the immediately preceding read operation or the sweep timing by the electronic shutter operation to the read timing by the current read operation serves as a charge accumulation period (also referred to as an exposure period) in the pixel 30.

Signals output from pixels 30 of a pixel row selectively scanned by the vertical drive circuit 22 are each input to the column processing circuit 23 through one of the vertical signal lines VSL of the respective pixel columns. The column processing circuit 23 performs predetermined signal processing on a signal output from each pixel of the selected row through a vertical signal line VSL for each pixel column of the pixel array unit 21 and temporarily holds the pixel signal after the signal processing.

Specifically, the column processing circuit 23 performs at least noise removal processing such as correlated double sampling (CDS) processing or double data sampling (DDS) processing as the signal processing. For example, the CDS processing removes fixed pattern noise unique to the pixels such as reset noise or threshold variations of the amplification transistors in the pixels. The column processing circuit 23 also has, for example, an analog-digital (AD) conversion function and converts analog pixel signals read from the photoelectric conversion elements into digital signals and outputs the digital signals.

The horizontal drive circuit 24 includes a shift register, an address decoder, and the like and sequentially selects readout circuits (hereinafter, also referred to as pixel circuits) corresponding to pixel columns of the column processing circuit 23. With the selective scanning by the horizontal drive circuit 24, the pixel signals subjected to signal processing for each pixel circuit in the column processing circuit 23 are sequentially output.

The system control unit 25 includes a timing generator that generates various timing signals and others and performs drive control of the vertical drive circuit 22, the column processing circuit 23, the horizontal drive circuit 24, and others on the basis of various types of timing generated by the timing generator.

The signal processing unit 26 has at least an arithmetic processing function and performs various types of signal processing such as arithmetic processing on the pixel signal output from the column processing circuit 23. The data storage unit 27 temporarily stores data necessary for signal processing in the signal processing unit 26.

Note that image data output from the signal processing unit 26 may be, for example, subjected to predetermined processing in the processor 13 or the like in the imaging device 1 mounted with the solid state imaging device 10 or transmitted to the outside via a predetermined network.

### 1.3 Configuration Example of Pixel

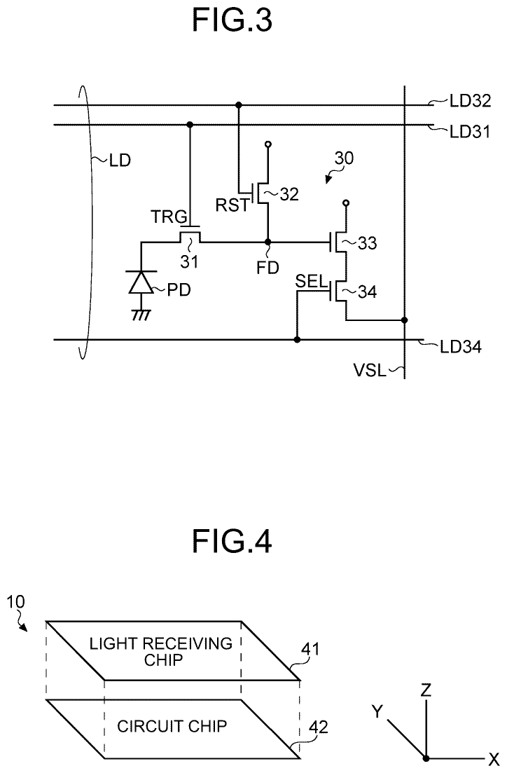

FIG. 3 is a circuit diagram illustrating a schematic configuration example of a pixel according to the present embodiment. As illustrated in FIG. 3, a pixel 30 includes a photoelectric conversion unit PD, a transfer transistor 31, a reset transistor 32, an amplification transistor 33, a selection transistor 34, and a floating diffusion region FD.

A selection transistor drive line LD34 included in a pixel drive line LD is connected to the gate of the selection transistor 34, a reset transistor drive line LD32 included in the pixel drive line LD is connected to the gate of the reset transistor 32, and a transfer transistor drive line LD31 included in the pixel drive line LD is connected to the gate of the transfer transistor 31. Furthermore, a vertical signal line VSL having one end connected to the column processing circuit 23 is connected to the source of the amplification transistor 33 via the selection transistor 34.

In the following description, the reset transistor 32, the amplification transistor 33, and the selection transistor 34 are also collectively referred to as a pixel circuit. The pixel circuit may include the floating diffusion region FD and/or the transfer transistor 31.

The photoelectric conversion unit PD photoelectrically converts light incident thereon. The transfer transistor 31 transfers charge generated in the photoelectric conversion unit PD. The floating diffusion region FD functions as a charge storage unit that stores the charge transferred by the transfer transistor 31. The amplification transistor 33 causes a pixel signal having a voltage value corresponding to the charge accumulated in the floating diffusion region FD to appear in the vertical signal line VSL. The reset transistor 32 releases the charge accumulated in the floating diffusion region FD. The selection transistor 34 selects the pixel 30 to be read.

The anode of the photoelectric conversion unit PD is grounded, and the cathode is connected to the source of the transfer transistor 31. The drain of the transfer transistor 31 is connected to the source of the reset transistor 32 and the gate of the amplification transistor 33, and a node which is a connection point of these transistors constitutes the floating diffusion region FD. Note that the drain of the reset transistor 32 is connected to a vertical reset input line (not illustrated).

The drain of the amplification transistor 33 is connected to a vertical voltage supply line (not illustrated). The source of the amplification transistor 33 is connected to the drain of the selection transistor 34, and the source of the selection transistor 34 is connected to the vertical signal line VSL.

The potential of the floating diffusion region FD is determined by the charge accumulated therein and the capacitance of the floating diffusion region FD. The capacitance of the floating diffusion region FD is determined by the capacitance of the drain diffusion layer of the transfer transistor 31, the capacitance of the source diffusion layer of the reset transistor 32, the capacitance of the gate of the amplification transistor 33, and the like, in addition to the capacitance-to-ground.

### 1.4 Example of Basic Function of Pixel

Next, a basic function of the pixel 30 will be described with reference to FIG. 3. The reset transistor 32 controls discharge (reset) of charge accumulated in the floating diffusion region FD in accordance with a reset signal RST supplied from the vertical drive circuit 22 via the reset transistor drive line LD32. Note that turning on the transfer transistor 31 while the reset transistor 32 is in the on state makes it possible to discharge (reset) also the charge accumulated in the photoelectric conversion unit PD in addition to the charge accumulated in the floating diffusion region FD.

When a high-level reset signal RST is input to the gate of the reset transistor 32, the potential of the floating diffusion region FD is clamped to a voltage applied through the vertical reset input line. As a result, the charge accumulated in the floating diffusion region FD is discharged (reset).

Furthermore, when a low-level reset signal RST is input to the gate of the reset transistor 32, the floating diffusion region FD is electrically disconnected from the vertical reset input line and enters a floating state.

The photoelectric conversion unit PD photoelectrically converts incident light and generates charge corresponding to the amount of light. The generated charge is accumulated on the cathode side of the photoelectric conversion unit PD. The transfer transistor 31 controls transfer of charge from the photoelectric conversion unit PD to the floating diffusion region FD in accordance with a transfer control signal TRG supplied from the vertical drive circuit 22 via the transfer transistor drive line LD31.

For example, when a high-level transfer control signal TRG is input to the gate of the transfer transistor 31, the charge accumulated in the photoelectric conversion unit PD is transferred to the floating diffusion region FD. Meanwhile, when a low-level transfer control signal TRG is supplied to the gate of the transfer transistor 31, the transfer of the charge from the photoelectric conversion unit PD is stopped.

As described above, the potential of the floating diffusion region FD when the reset transistor 32 is turned off is determined by the amount of charge transferred from the photoelectric conversion unit PD via the transfer transistor 31 and the capacitance of the floating diffusion region FD.

The amplification transistor 33 functions as an amplifier using potential fluctuations of the floating diffusion region FD connected to the gate thereof as an input signal, and an output voltage signal thereof appears as a pixel signal in the vertical signal line VSL via the selection transistor 34.

The selection transistor 34 controls the appearance of the pixel signal by the amplification transistor 33 in the vertical signal line VSL in accordance with a selection control signal SEL supplied from the vertical drive circuit 22 via the selection transistor drive line LD34. For example, when a high-level selection control signal SEL is input to the gate of the selection transistor 34, a pixel signal by the amplification transistor 33 appears in the vertical signal line VSL. Meanwhile, when a low-level selection control signal SEL is input to the gate of the selection transistor 34, the appearance of the pixel signal in the vertical signal line VSL is stopped. This makes it possible to extract only the output of a selected pixel 30 in the vertical signal line VSL to which a plurality of pixels 30 is connected.

### 1.5 Stacked Structure Example of Solid State Imaging Device

FIG. 4 is a diagram illustrating a stacked structure example of the image sensor according to the embodiment. As illustrated in FIG. 4, the solid state imaging device 10 has a structure in which the light receiving chip 41 and the circuit chip 42 are vertically stacked. The light receiving chip 41 has a structure in which the light receiving chip 41 and the circuit chip 42 are stacked. The light receiving chip 41 is, for example, a semiconductor chip including the pixel array unit 21 in which the photoelectric conversion units PD are arrayed, and the circuit chip 42 is, for example, a semiconductor chip in which pixel circuits are arrayed.

For joining the light receiving chip 41 and the circuit chip 42, for example, so-called direct joining can be used in which the joining surfaces thereof are planarized and joined to each other by interelectronic force. However, without being limited thereto, it is also possible to use, for example, so-called Cu—Cu joining, in which copper (Cu) electrode pads formed on joint surfaces thereof are joined to each other, bump joining, or the like.

In addition, the light receiving chip 41 and the circuit chip 42 are electrically connected via a connecting portion such as a through-silicon via (TSV) which is a through contact penetrating the semiconductor substrate, for example. For the connection using the TSV, for example, a so-called twin TSV method in which two TSVs, namely, a TSV included in the light receiving chip 41 and a TSV included from the light receiving chip 41 to the circuit chip 42 are connected on an outer surface of the chip, a so-called shared TSV method in which the light receiving chip 41 and the circuit chip 42 are connected by a TSV penetrating from the light receiving chip 41 to the circuit chip 42, or other methods can be adopted.

However, in a case where Cu—Cu joining or bump joining is used for joining the light receiving chip 41 and the circuit chip 42, the light receiving chip 41 and the circuit chip 42 are electrically connected via a Cu—Cu joining portion or a bump joining portion.

### 1.6 Basic Structure Example of Pixels

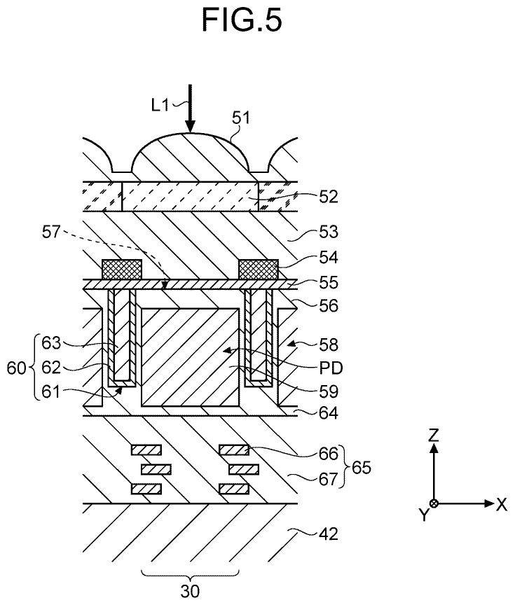

Next, a basic structure example of a pixel 30 in the solid state imaging device 10 according to the first embodiment will be described with reference to FIG. 5. FIG. 5 is a cross-sectional view illustrating a basic cross-sectional structure example of a pixel according to the first embodiment. Note that illustrated in FIG. 5 is a cross-sectional structure example of the light receiving chip 41 in which the photoelectric conversion unit PD in the pixel 30 is disposed.

As illustrated in FIG. 5, in the solid state imaging device 10, the photoelectric conversion unit PD receives incident light L1 incident from the back surface (top surface in the drawing) side of a semiconductor substrate 58. Above the photoelectric conversion unit PD, a planarization film 53, a color filter 52, and an on-chip lens 51 are provided, and photoelectric conversion is performed on the incident light L1 incident on the semiconductor substrate 58 from a light receiving surface 57 by sequentially passing through the above components.

As the semiconductor substrate 58, for example, a semiconductor substrate made of a group IV semiconductor including at least one of carbon (C), silicon (Si), germanium (Ge), or tin (Sn) or a semiconductor substrate made of a group III-V semiconductor including at least two of boron (B), aluminum (Al), gallium (Ga), indium (In), nitrogen (N), phosphorus (P), arsenic (As), and antimony (Sb) may be used. However, it is not limited thereto, and various semiconductor substrates may be used.

The photoelectric conversion unit PD may have, for example, a structure in which N-type semiconductor regions 59 are formed as charge accumulation regions that accumulate charge (electrons). In the photoelectric conversion unit PD, the N-type semiconductor regions 59 are provided in regions surrounded by P-type semiconductor regions 56 and 64 of the semiconductor substrate 58. The P-type semiconductor region 64 having a higher impurity concentration than that of the back surface (top surface) side is included on the front surface (lower surface) side of the semiconductor substrate 58 in the N-type semiconductor regions 59. That is, the photoelectric conversion unit PD has a hole-accumulation diode (HAD) structure, and the P-type semiconductor regions 56 and 64 are provided in such a manner as to suppress generation of a dark current at each of interfaces on the top surface side and the lower surface side of the N-type semiconductor regions 59.

A pixel separation unit 60 that electrically separates a plurality of pixels 30 from each other is included inside the semiconductor substrate 58, and the photoelectric conversion unit PD is included in the region partitioned by the pixel separation unit 60. In the drawing, in a case where the solid state imaging device 10 is viewed from the top surface side, for example, the pixel separation unit 60 is provided in a lattice shape in such a manner as to be interposed between the plurality of pixels 30, and the photoelectric conversion unit PD is disposed in the regions partitioned by the pixel separation unit 60.

The anode of each photoelectric conversion unit PD is grounded, and in the solid state imaging device 10, the signal charge (for example, electrons) accumulated by the photoelectric conversion unit PD is read out via the transfer transistor 31 (not illustrated) (see FIG. 3) or the like and output to the vertical signal line VSL (not illustrated) (see FIG. 3) as an electric signal.

A wiring layer 65 is provided on the front surface (lower surface) of the semiconductor substrate 58 on a side opposite to the back surface (top surface) on which the components such as a light shielding film 54, the planarization film 53, the color filter 52, and the on-chip lens 51 are provided.

The wiring layer 65 includes wiring 66, an insulating layer 67, and a through electrode (not illustrated). An electric signal from the light receiving chip 41 is transmitted to the circuit chip 42 via the wiring 66 and the through electrode (not illustrated). Similarly, the substrate potential of the light receiving chip 41 is also applied from the circuit chip 42 via the wiring 66 and the through electrode (not illustrated).

The circuit chip 42 illustrated in FIG. 4, for example, is joined to a surface of the wiring layer 65 on a side opposite to the side on which the photoelectric conversion unit PD is provided.

The light shielding film 54 is provided on the back surface (top surface in the drawing) side of the semiconductor substrate 58 and shields a part of the incident light L1 incident from above the semiconductor substrate 58 toward the back surface of the semiconductor substrate 58.

The light shielding film 54 is provided above the pixel separation unit 60 included inside the semiconductor substrate 58. Incidentally, the light shielding film 54 is provided in such a manner as to protrude rectangularly on the back surface (top surface) of the semiconductor substrate 58 with an insulating film 55, such as a silicon oxide film, interposed therebetween. Meanwhile, above the photoelectric conversion unit PD included inside the semiconductor substrate 58, the light shielding film 54 is not provided and is open so that the incident light L1 enters the photoelectric conversion unit PD.

That is, when the solid state imaging device 10 is viewed from the top surface side in the drawing, the planar shape of the light shielding film 54 is a lattice shape, and an opening through which the incident light L1 passes to the light receiving surface 57 is formed.

The light shielding film 54 is formed of a light shielding material that shields light. For example, the light shielding film 54 is formed by sequentially stacking a titanium (Ti) film and a tungsten (W) film. Alternatively, the light shielding film 54 can be formed by sequentially stacking a titanium nitride (TiN) film and a tungsten (W) film, for example.

The light shielding film 54 is covered with the planarization film 53. The planarization film 53 is formed using an insulating material that transmits light. As the insulating material, for example, silicon oxide (SiO₂) or the like can be used.

The pixel separation unit 60 includes, for example, a groove 61, a fixed charge film 62, and an insulating film 63 and is included on the back surface (top surface) side of the semiconductor substrate 58 in such a manner as to cover the groove 61 that partitions the plurality of pixels 30.

Specifically, the fixed charge film 62 is included in such a manner as to cover the inner surface of the groove 61 formed on the back surface (top surface) side of the semiconductor substrate 58 with a constant thickness. The insulating film 63 is further included (fills) in such a manner as to fill the inside of the groove 61 covered with the fixed charge film 62.

Incidentally, the fixed charge film 62 is formed using a high dielectric having a negative fixed charge such that a positive charge (hole) accumulation region is formed at an interface with the semiconductor substrate 58 and that generation of a dark current is suppressed. Since the fixed charge film 62 has a negative fixed charge, an electric field is applied to the interface with the semiconductor substrate 58 due to the negative fixed charge, and a positive charge (hole) accumulation region is formed.

The fixed charge film 62 can be formed of, for example, a hafnium oxide film (HfO₂ film). In addition, the fixed charge film 62 can be formed to contain at least one of oxides such as hafnium, zirconium, aluminum, tantalum, titanium, magnesium, yttrium, or lanthanoids.

Note that the pixel separation unit 60 is not limited to the above structure and can be modified in various manners. For example, by using a reflection film that reflects light, such as a tungsten (W) film, instead of the insulating film 63, the pixel separation unit 60 can have a light-reflecting structure. As a result, the incident light L1 entering the photoelectric conversion unit PD can be reflected by the pixel separation unit 60, and thus the optical path length of the incident light L1 in the photoelectric conversion unit PD can be increased. In addition, with the pixel separation unit 60 having the light-reflecting structure, it is possible to reduce leakage of light to adjacent pixels, and thus, it is also possible to further improve the image quality, ranging accuracy, and the like. Note that, in a case where a metal material such as tungsten (W) is used as the material of the reflection film, it is preferable to include an insulating film such as a silicon oxide film in the groove 61 instead of the fixed charge film 62. Furthermore, the structure in which the pixel separation unit 60 has the light-reflecting structure is not limited to the structure using the reflection film and can be implemented, for example, by embedding a material having a higher refractive index or a lower refractive index than that of the semiconductor substrate 58 in the groove 61.

Furthermore, illustrated as an example in FIG. 5 is the pixel separation unit 60 having a so-called reverse deep trench isolation (RDTI) structure in which the pixel separation unit 60 is included in the groove 61 formed from the back surface (top surface) side of the semiconductor substrate 58; however, it is not limited thereto. It is possible to adopt a pixel separation unit 60 of various structures such as a so-called deep trench isolation (DTI) structure in which the pixel separation unit 60 is included in the groove formed from the front surface (lower surface) side of the semiconductor substrate 58 or a so-called full trench isolation (FTI) structure in which the pixel separation unit 60 is included in the groove formed in such a manner as to penetrate the front and back surfaces of the semiconductor substrate 58.

### 1.7 Schematic Cross-Sectional Structure Example of Image Plane Phase Difference Pixel

Next, a schematic structure example of a pixel (hereinafter, also referred to as an image plane phase difference pixel) configured as a pixel pair capable of acquiring an image plane phase difference will be described on the basis of the basic structure example of the pixel 30 illustrated in FIG. 5.

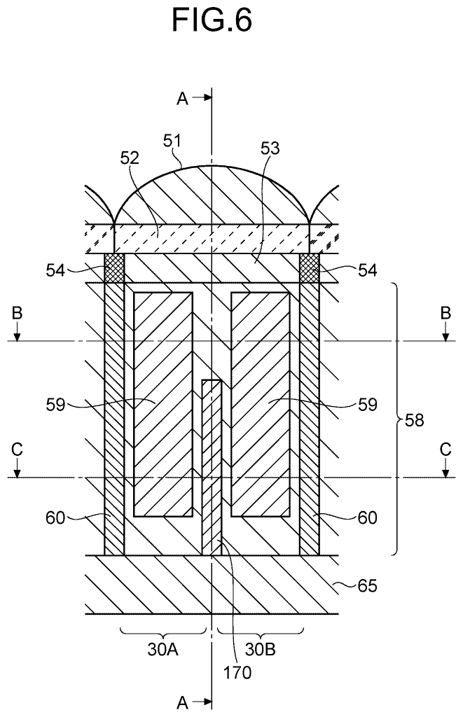

FIG. 6 is a vertical cross-sectional view illustrating a schematic structure example of an image plane phase difference pixel according to the embodiment. Note that, in FIG. 6, similar components to those in FIG. 5 are denoted by the same symbols, and redundant description thereof will be omitted. However, the structure illustrated in FIG. 6 is slightly modified from the structure illustrated in FIG. 5 in parts other than the characteristic structure of the present embodiment without departing from the scope of the technical matters according to the present disclosure. Furthermore, in order to simplify the description, the pixel structure is omitted or simplified as necessary in FIG. 6 and the following description.

As illustrated in FIG. 6, the image plane phase difference pixel according to the present embodiment has a structure in which two pixels 30A and 30B share one on-chip lens 51 and one color filter 52. Note that, in the present example, a case where two pixels 30A and 30B adjacent in the row direction or the column direction constitute one image plane phase difference pixel, namely, a case where the two pixels 30A and 30B share one on-chip lens 51 and one color filter 52 will be described as an example; however, it is not limited thereto and various modifications may be made such as a case where four pixels 30 arranged in two rows and two columns share one on-chip lens 51 and one color filter 52, a case where either one on-chip lens 51 or one color filter 52 is shared by a plurality of pixels 30 adjacent in the row direction and/or the column direction, or a case where an image plane phase difference pixel is constituted by adjacent pixels 30 that do not share any of the on-chip lens 51 nor the color filter 52.

A pair of pixels 30A and 30B constituting one image plane phase difference pixel and other pixels 30 arranged in such a manner as to surround the pair are optically and electrically separated by the pixel separation unit 60. Note that illustrated as an example in FIG. 6 is a case where the pixel separation unit 60 has a so-called FTI structure (penetrating structure) penetrating the semiconductor substrate 58. Furthermore, in FIG. 6 and FIGS. 7 to 9, FIGS. 11 to 22, and FIG. 27 to be described later, the structure of the pixel separation unit 60 is illustrated in a simplified manner.

Meanwhile, the pixels 30A and 30B constituting one image plane phase difference pixel are electrically separated from each other by a pixel separation unit (hereinafter, also referred to as an in-pixel separation unit) 170 disposed at a position partitioning a region (for example, a rectangular region) partitioned by the pixel separation unit 60 into two.

The in-pixel separation unit 170 disposed between the pixels 30A and 30B has, for example, a so-called DTI structure (non-penetrating structure) that extends from the back surface (corresponding to the light incident surface) side of the semiconductor substrate 58 toward the front surface (corresponding to the element formation surface) side to such an extent as not to penetrate the semiconductor substrate 58.

As described above, with the separation unit (in-pixel separation unit 170) between the pixels 30A and 30B constituting one image plane phase difference pixel having a non-penetrating structure, a part of the semiconductor substrate 58 is continuous across the pixels 30A and 30B. The part where the semiconductor substrate 58 is continuous functions as an intercolor path (hereinafter, also referred to as an overflow path) for releasing a carrier to the other pixel when one of the pixels 30A and 30B is saturated. As described above, since the pixels 30A and 30B constituting one image plane phase difference pixel are so-called same-color pixels sharing the same-color filter 52, it is possible to reduce a difference in light receiving sensitivity between the pixels 30A and 30B due to a process error or the like by electrically connecting the pixels 30A and 30B by an overflow path.

Note that, in the above-described structure, light incident via the on-chip lens 51 and the color filter 52 is photoelectrically converted in the photoelectric conversion unit PD (N-type semiconductor region 59 and P-type semiconductor regions 56 and 64 (see FIG. 5) surrounding the N-type semiconductor regions 59) in either the pixel 30A (hereinafter, also referred to as a left pixel) or the pixel 30B (hereinafter, also referred to as a right pixel) that are physically and electrically separated, whereby electrons to be charge to be read are generated. The generated electrons are sequentially transferred to the floating diffusion region FD of the pixel circuit via the transfer transistor 31 and are read as pixel signals of the pixels 30A and 30B. The signal processing unit 26 to which the read pixel signals are input detects a phase difference by comparing signal amounts of the left pixel 30A and the right pixel 30B and calculates an appropriate focal length on the basis of the detected phase difference.

### 1.8 Problem in Image Plane Phase Difference Pixel Structure

Incidentally, as described above, in the back-illuminated solid state imaging device 10, in a case where individual image plane phase difference pixels (hereinafter, also referred to as different-color pixels) are optically and electrically separated by a penetrating structure, and the inside of one image plane phase difference pixel is electrically separated by a non-penetrating structure capable of forming an overflow path, characteristics of high reflectance and high insulating properties are required for the separation material (namely, the material of the pixel separation unit 60) for separation between different-color pixels, whereas characteristics of low reflectance, low insulating properties, and non-photoelectric conversion properties are required for the separation material (namely, the material of the in-pixel separation unit 170) for separation between the same-color pixels. That is, different characteristics are required for the pixel separation unit 60 and the in-pixel separation unit 170. In the case where the required characteristics are different as described above, there is a problem that it is not easy to manufacture internal materials separately.

For example, in order to optimize the structure of each of the pixel separation unit 60 having a penetrating structure and the in-pixel separation unit 170 having a non-penetrating structure, it is necessary to simultaneously remove a film formed around the image plane phase difference pixel (in a through hole or a trench in which the pixel separation unit 60 is formed) by isotropic etching such as wet etching at the time of forming the in-pixel separation unit 170; however, there is a possibility that the in-pixel separation unit 170 is also removed at the same time in the removal step.

Therefore, in the present embodiment, a structure is adopted in which a layer or a region functioning as an etching stopper at the time of processing (namely, removing the film formed around the image plane phase difference pixel) the in-pixel separation unit 170 is disposed between the pixel separation unit 60 (or the through hole or the trench in which the pixel separation unit 60 is formed) and the in-pixel separation unit 170 (or the trench in which the in-pixel separation unit 170 is formed). As a result, in the step of removing the film formed around the image plane phase difference pixel simultaneously with formation of the in-pixel separation unit 170, it is possible to significantly reduce the region removed from the in-pixel separation unit 170, and thus, it becomes possible to separately form the pixel separation unit 60 easily and the in-pixel separation unit 170 having different required characteristics. As a result, it is possible to prevent the light incident in an oblique direction from the back surface side of the substrate, serving as the light irradiation surface, from being blocked by the in-pixel separation unit 170, and thus, it is possible to implement the solid state imaging device and the electronic apparatus in which a decrease in the light receiving sensitivity is suppressed.

### 1.9 Cross-Sectional Structure Example of Image Plane Phase Difference Pixel

Next, a structure example of the image plane phase difference pixel according to the present embodiment will be described in more detail including the structure example described with reference to FIG. 6.

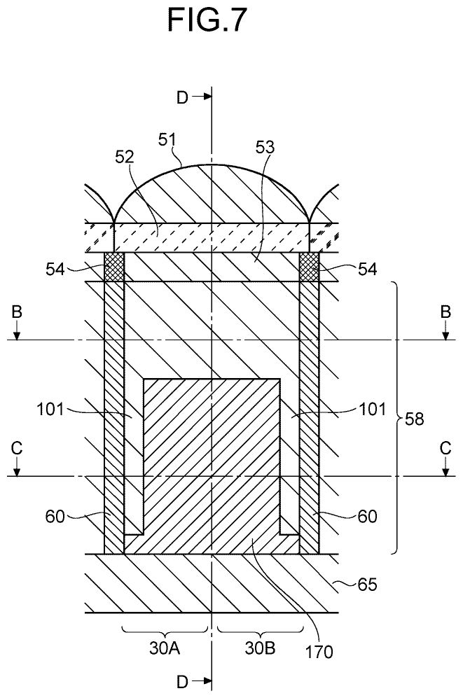

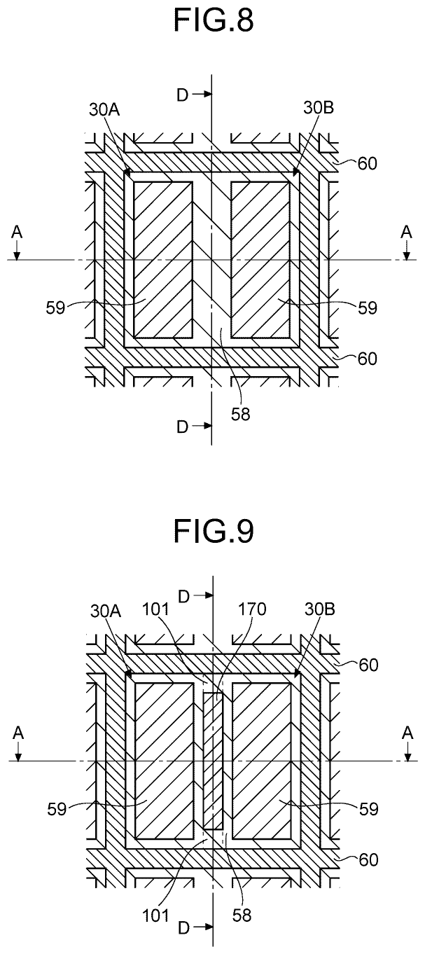

FIG. 7 is a vertical cross-sectional view illustrating a schematic structure example of the image plane phase difference pixel according to the embodiment when cut along a plane different from that in FIG. 6. Note that FIG. 6 is a cross-sectional view of the light receiving chip 41 cut along a plane (D-D plane) perpendicular to the element formation surface of the semiconductor substrate 58, the plane parallel to the array direction of the pixels 30A and 30B, and FIG. 7 is a cross-sectional view of the light receiving chip 41 cut along a plane (A-A plane) perpendicular to the element formation surface of the semiconductor substrate 58, the plane parallel to the array direction of the pixels 30A and 30B. Furthermore, FIG. 8 is a horizontal cross-sectional view illustrating a schematic structure example of the image plane phase difference pixel according to the present embodiment, and FIG. 9 is a horizontal cross-sectional view illustrating a schematic structure example of the image plane phase difference pixel according to the present embodiment when cut along a plane different from that in FIG. 8. Note that FIG. 8 is a diagram illustrating a cross-sectional structure example of a C-C plane in FIGS. 6 and 7, and FIG. 9 is a diagram illustrating a cross-sectional structure example of a D-D plane in FIGS. 6 and 7.

As illustrated in FIGS. 6 to 9, the image plane phase difference pixel according to the present embodiment has a structure in which, for example, a rectangular image plane phase difference pixel region partitioned by the pixel separation unit 60 included between the image plane phase difference pixels is divided into two rectangular pixel regions, for example, by the in-pixel separation unit 170 disposed in such a manner as to pass through the center of the pixel region.

In the present embodiment, as the material of the pixel separation unit 60, for example, one or a plurality of materials having characteristics of high reflectance and high insulating properties, such as silicon oxide (SiO₂), tungsten (W), or aluminum (Al), may be used. On the other hand, as the material of the in-pixel separation unit 170, one or a plurality of materials having characteristics of low reflectance, low insulating properties, and non-photoelectric conversion properties, such as diamond, diamond-like carbon (DLC), titanium oxide (TiO₂), cerium oxide (CeO₂), iron oxide (Fe₂O₃), or silicon nitride (SiN), may be used.

In such a configuration, in at least a part of the region between the pixel separation unit 60 and the in-pixel separation unit 170, a layer or a region (hereinafter, also referred to as an etching stopper region 101) made of a material capable of sufficiently achieving etch selectivity to the material used for the in-pixel separation unit 170 is disposed. For example, a partial region of the semiconductor substrate 58 can be used for the etching stopper region 101. In that case, a material capable of sufficiently achieving etch selectivity with respect to the material (for example, silicon (Si)) constituting the semiconductor substrate 58 is used for the in-pixel separation unit 170.

With such a configuration, in the step of removing the film formed around the image plane phase difference pixel (the region where the pixel separation unit 60 is formed) simultaneously with formation of the in-pixel separation unit 170, it is possible to significantly reduce the region removed from the in-pixel separation unit 170, and thus, it becomes possible to separately form the pixel separation unit 60 easily and the in-pixel separation unit 170 having different required characteristics.

### 1.10 Manufacturing Method

Next, a manufacturing method of the solid state imaging device 10 according to the present embodiment will be described together with the effects of including the above-described structure. Note that, in the following description, a case where the transfer transistor 31 among the transistors (Transfer transistor 31, reset transistor 32, amplification transistor 33, and selection transistor 34) included in the pixel circuit for reading out charge from the photoelectric conversion unit PD is disposed in the same light receiving chip 41 as the photoelectric conversion unit PD is disposed will be described as an example; however, it is not limited thereto, and at least one transistor other than the transfer transistor 31 may also be disposed in the light receiving chip 41.

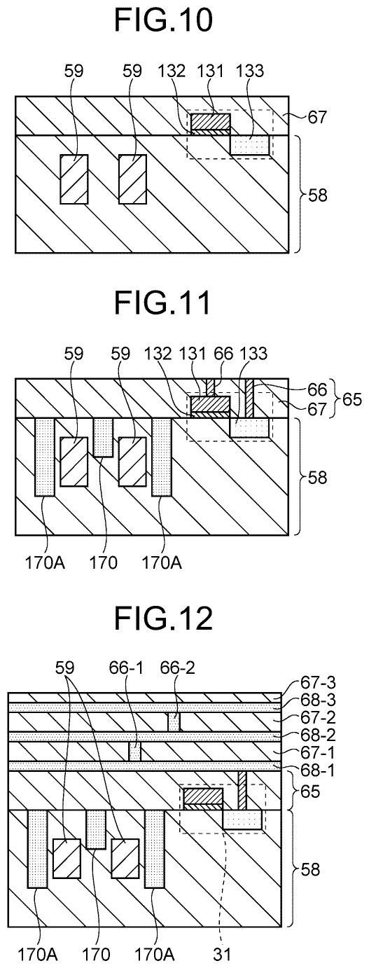

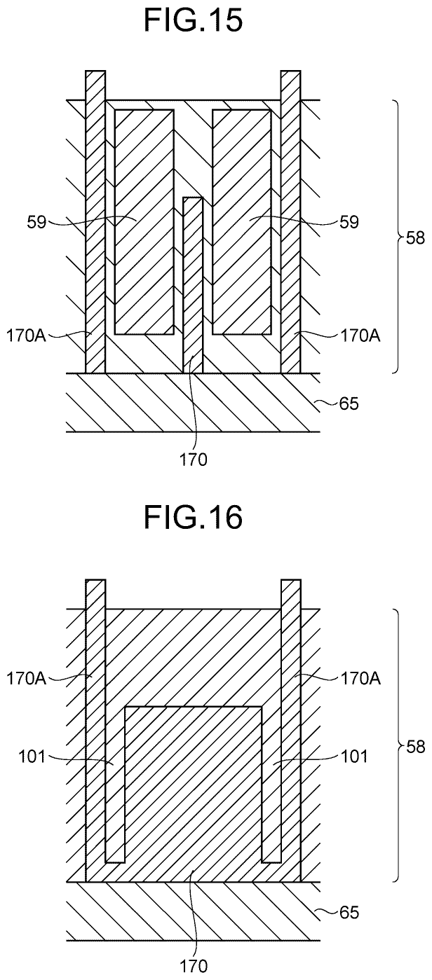

FIGS. 10 to 14 are process cross-sectional views for explaining the manufacturing method of the solid state imaging device according to the present embodiment. Furthermore, FIGS. 15 to 20 are process cross-sectional views focusing on a manufacturing process of the pixel separation unit in the manufacturing method of the solid state imaging device of the embodiment.

In the present manufacturing method, first, as illustrated in FIG. 10, the semiconductor substrate (for example, a silicon wafer) 58 having P-type conductivity is prepared, and the N-type semiconductor regions 59 included in the photoelectric conversion unit PD are formed in the semiconductor substrate 58.

The N-type semiconductor regions 59 in the semiconductor substrate 58 can be formed, for example, by implanting predetermined ions with predetermined implantation energy and a predetermined dosage into a predetermined region from the front surface side of the semiconductor substrate 58 using a photoresist or a hard mask formed using lithography technology. Note that the ions implanted in the following ion implantation step including this step and other embodiments may be thermally diffused and activated by heat treatment such as annealing at any time or in a predetermined step.

Subsequently, by using an existing semiconductor process, the transfer transistor 31 is formed on the element formation surface of the semiconductor substrate 58, and the element formation surface of the semiconductor substrate 58 on which the transfer transistor 31 is formed is covered with the insulating layer 67.

Specifically, for example, a gate insulating film 132 and a gate electrode 131 are formed in a predetermined region on the semiconductor substrate 58, and then a predetermined dopant is ion-implanted into a predetermined region on the element formation surface to form a diffusion region 133. The diffusion region 133 thus formed and a diffusion region constituting the cathode of the photoelectric conversion unit PD function as a source and a drain of the transfer transistor 31. Further, for forming the insulating layer 67, for example, a chemical vapor deposition (CVD) method, sputtering, or the like can be used. Note that a top surface of the insulating layer 67 may be planarized by, for example, chemical mechanical polishing (CMP).

Next, as illustrated in FIG. 11, by digging the semiconductor substrate 58 from the element formation surface, a first trench (also referred to as a through trench) for forming the pixel separation unit 60 that partitions the image plane phase difference pixel and a second trench (also referred to as a non-through trench) for forming the in-pixel separation unit 170 that partitions the pixel region partitioned by the pixel separation unit 60 are formed.

For example, lithography technology can be used to form the first and second trenches. That is, the first and second trenches may be formed by forming a resist film or a hard mask may be formed on the element formation surface of the semiconductor substrate 58 by photolithography and digging the semiconductor substrate 58 via the mask by dry etching such as reactive ion etching (RIE).

The etching condition of RIE when the first trench and the second trench are hollowed out may be set as follows, for example.
Chamber internal pressure: 5 to 100 (millitorr (mTorr))
Source power: 500 to 2000 (watts (W))
Bias power: 100 to 1000 (W)
Chlorine gas flow: 10 to 300 (cubic centimetre per minute (sccm)
Oxygen gas flow: 1 to 50 sccm

In addition, the opening width (also referred to as a line width) of the mask at the time of forming the first and second trenches may be, for example, about 0.01 micrometers (μm) to 0.5 μm. In addition, the depth of the first trench after processing may be, for example, greater than or equal to 0.1 μm.

Note that the first trench and the second trench can be formed in the same step by adjusting the line width of the mask but may also be formed in separate steps. That is, by controlling the etching speed in the depth direction by adjusting the line width of the mask, it is also possible to create the first trench and the second trench having different depths in the same step. In addition, a contact hole for forming the wiring 66 in contact with each of the gate electrode 131 and the diffusion region may be formed in the same step as the formation of the first trench and/or the second trench or formed in separate steps.

Subsequently, by filling the second trench with a predetermined material using, for example, a chemical vapor deposition (CVD) method, sputtering, or the like, the in-pixel separation unit 170 is formed in the second trench. The predetermined material may have low reflectance, low insulating properties, and non-photoelectric conversion properties as described above. At this point, a film 170A made of the same material as that of the in-pixel separation unit 170 may be formed in the first trench. In addition, the material deposited on the element formation surface of the semiconductor substrate 58 may be removed by a method such as chemical mechanical polishing (CMP) or lift-off. Furthermore, the opening formed in the insulating layer 67 to form the in-pixel separation unit 170 and the film 170A may be filled with the same material as that of the insulating layer 67.

Subsequently, by filling a conductive material in the contact hole formed in the insulating layer 67, the pieces of wiring 66 electrically connected to the gate electrode 131 and the diffusion region 133 are each formed.

Next, as illustrated in FIG. 12, a multilayer wiring layer including wiring layers 68-1, 68-2, and 68-3 electrically connected to circuit elements such as the transfer transistor 31, interlayer insulating films 67-1, 67-2, and 67-3 that insulate the layers, and via wiring 66-1 and 66-2 that electrically connects the wiring layers 68-1, 68-2, and 68-3 of the layers is formed on the element formation surface of the semiconductor substrate 58.

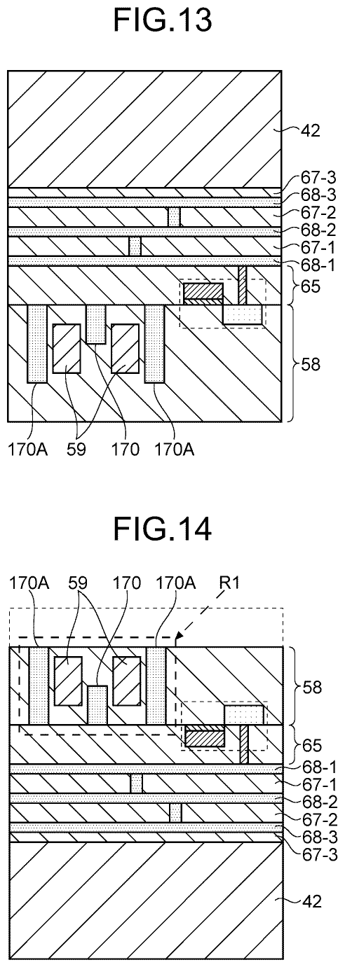

Next, as illustrated in FIG. 13, the circuit chip 42 made of, for example, a silicon substrate or the like is joined onto the multilayer wiring layer. As for joining the chips, for example, various joining methods may be used such as direct joining in which the top surface of the multilayer wiring layer and a joining surface of the circuit chip 42 are each planarized and the two are joined by interelectronic force or a joining mode (Cu—Cu joining) in which a metal pad made of copper (Cu) or the like formed on the top surface of the multilayer wiring layer and a metal pad made of copper (Cu) or the like formed on the joining surface of the circuit chip 42 are joined together.

Next, as illustrated in FIG. 14, the semiconductor substrate 58 to which the circuit chip 42 is joined on the element formation surface side is inverted, and the semiconductor substrate 58 is thinned with high accuracy from the back surface (light incident surface) side, thereby exposing the bottom portion of the film 170A embedded in the first trench in which the pixel separation unit 60 is formed. For thinning the semiconductor substrate 58, one or a combination of two or more of CMP, dry etching, wet etching, and the like may be used. Note that this thinning step does not exclude that at least a part of the bottom portion of the film 170A is removed.

Next, a manufacturing process of the pixel separation unit 60 that separates an image plane phase difference pixel will be described focusing on a region R1 in FIG. 14. Note that FIGS. 15, 17, and 19 are process cross-sectional views of a cross section corresponding to that in FIG. 6 in the above description, and FIGS. 16, 18, and 20 are process cross-sectional views of a cross section corresponding to that in FIG. 7 in the above description.

As illustrated in FIGS. 15 and 16, at the stage where the thinning step illustrated in FIG. 14 is completed, a film 170A made of the same material as the in-pixel separation unit 170 is formed in the first trench in which the pixel separation unit 60 is formed. Therefore, for example, in a case where it is attempted to remove the film 170A by an isotropic etching method such as wet etching, there is a possibility that the in-pixel separation unit 170 made of the same material is removed over a wide range.

Therefore, in the present embodiment, as described above, the etching stopper region 101 made of a material capable of securing the etch selectivity with respect to the constituent material of the in-pixel separation unit 170 is disposed at least partially between the film 170A formed in the first trench and the in-pixel separation unit 170 formed in the second trench. As a result, it is possible to prevent or to suppress removal of a part of the in-pixel separation unit 170 at the time of removal of the film 170A, and thus it is possible to separately form the pixel separation unit 60 easily and the in-pixel separation unit 170 having different required characteristics.

Note that, as a constituent material of the etching stopper region 101, for example, a constituent material of the semiconductor substrate 58 (namely, a part of the semiconductor substrate 58) can be used. As a result, it is possible to avoid complication of the manufacturing process, and thus it is possible to suppress a decrease in yield.

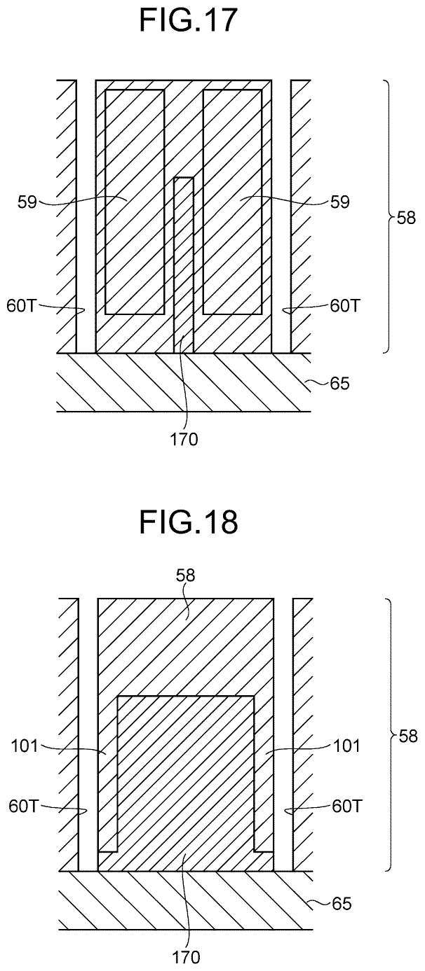

Specifically, as illustrated in FIGS. 17 and 18, first, the film 170A is removed from the back surface (top surface in FIGS. 17 and 18) side of the semiconductor substrate 58 by, for example, wet etching. At this point, as the etchant, etchant capable of securing etch selectivity with respect to the material (in the present example, the material of the semiconductor substrate 58) included in the etching stopper region 101 may be used. Accordingly, the contact of the etchant with the in-pixel separation unit 170 is prevented or limited by the etching stopper region 101, and thus it is possible to prevent or to suppress removal of a part of the in-pixel separation unit 170 at the time of removal of the film 170A.

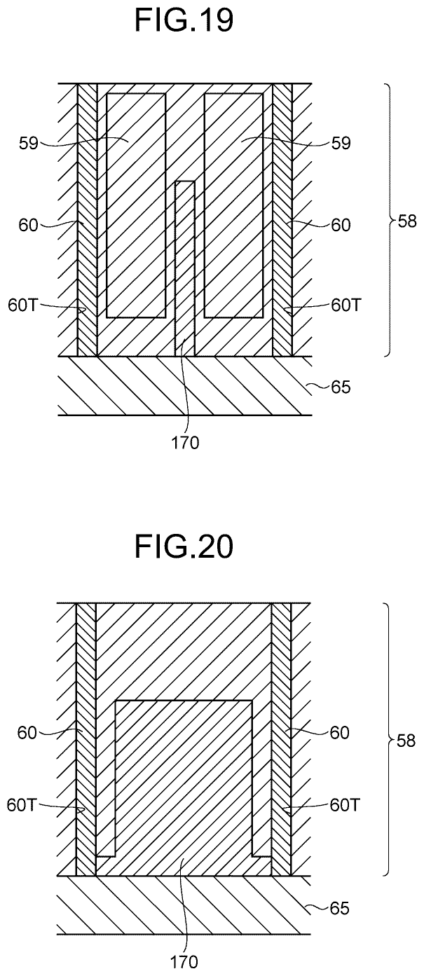

Next, as illustrated in FIGS. 19 and 20, the pixel separation unit 60 is formed by embedding a material having high reflectance and high insulating properties in a trench 60T formed by removing the film 170A. Note that film forming technology such as the CVD method or sputtering may be used as appropriate for forming the pixel separation unit 60. Furthermore, as illustrated in FIG. 5, the pixel separation unit 60 may have a stacked structure of the fixed charge film 62 made of a high dielectric constant material and the insulating film 63 or a metal film. Incidentally, materials deposited on the back surface of the semiconductor substrate 58 may be removed by CMP, wet etching, or the like.

Thereafter, the light shielding film 54 and the planarization film 53 are formed on the back surface of the semiconductor substrate 58, and subsequently, the color filter 52 and the on-chip lens 51 are sequentially formed on the planarization film 53, whereby the solid state imaging device 10 including the image plane phase difference pixel having the cross-sectional structure illustrated in FIGS. 6 to 9 is manufactured.

### 1.11 Summary

As described above, according to the present embodiment, the etching stopper region 101 made of a material capable of securing the etch selectivity with respect to the constituent material of the in-pixel separation unit 170 is disposed at least partially between the pixel separation unit 60 and the in-pixel separation unit 170. As a result, in the manufacturing process, when the film 170A made of the same material as that of the in-pixel separation unit 170 formed in the trench (first trench) in which the pixel separation unit 60 is formed is removed, it is possible to prevent or to suppress removal of a part of the in-pixel separation unit 170. Therefore, even in a case where materials corresponding to the characteristics required for each of the pixel separation unit 60 and the in-pixel separation unit 170 are used as the constituent materials thereof, it is possible to separately form the pixel separation unit 60 easily and the in-pixel separation unit 170. As a result, it is possible to implement the solid state imaging device 10 and the electronic apparatus in which a high refractive index (namely, low reflectance), high insulation properties, and non-photoelectric conversion properties are achieved between same-color pixels desired to be electrically separated without being optically separated while a low refractive index (namely, high reflectance) and high insulating properties are achieved between different-color pixels desired to be optically and electrically separated.

In addition, by making the separation structure between the same-color pixels a physically separating structure and not a separation structure by an ion diffusion region, it becomes possible to relax the electric field to the floating diffusion region FD beside the separation.

### 1.12 Modifications

Next, modifications of the first embodiment described above will be described with some examples.

### 1.12.1 First Modification

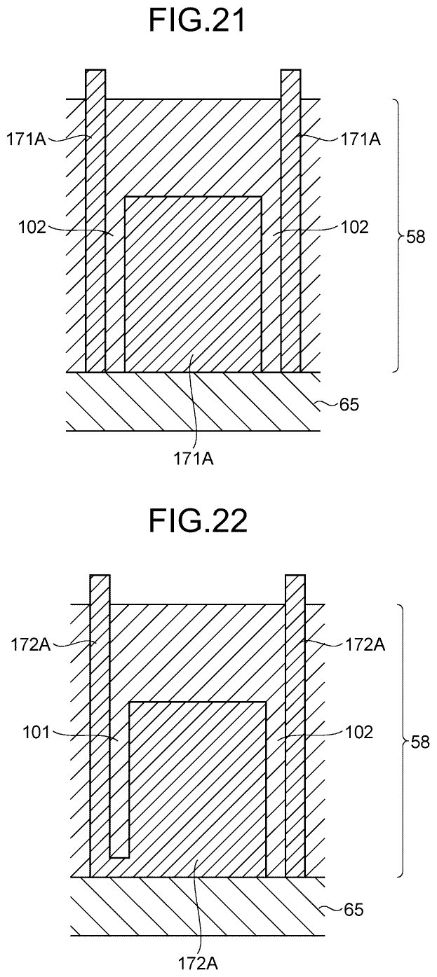

FIG. 21 is a vertical cross-sectional view illustrating a cross-sectional structure example of an image plane phase difference pixel in the middle of manufacturing according to a first modification, the cross-sectional structure example in a step corresponding to that in FIG. 16.

In the first embodiment described above, the etching stopper region 101 is disposed at least partially between the pixel separation unit 60 (or the film 170A) and the in-pixel separation unit 170. For example, in the first embodiment, as illustrated in FIGS. 7 and 16 as an example, the pixel separation unit 60 (or the film 170A) and the in-pixel separation unit 170 are connected on the back surface side of the semiconductor substrate 58.

Meanwhile, as illustrated in FIG. 21, in the first modification, the pixel separation unit 60 (or the film 170A) and the in-pixel separation unit 170 may be completely separated by an etching stopper region 102. That is, the etching stopper region 102 may be disposed in the entire range between the pixel separation unit 60 (or the film 170A) and the in-pixel separation unit 170.

As described above, by completely separating the pixel separation unit 60 (or the film 170A) and the in-pixel separation unit 170 by the etching stopper region 102, it becomes possible to prevent or to strongly suppress the removal of the in-pixel separation unit 170 at the time of removal of the film 170A, and thus, it is possible to more easily form the pixel separation unit 60 and the in-pixel separation unit 170 having different required characteristics separately. As a result, it is made possible to easily implement a configuration capable of suppressing a decrease in light receiving sensitivity.

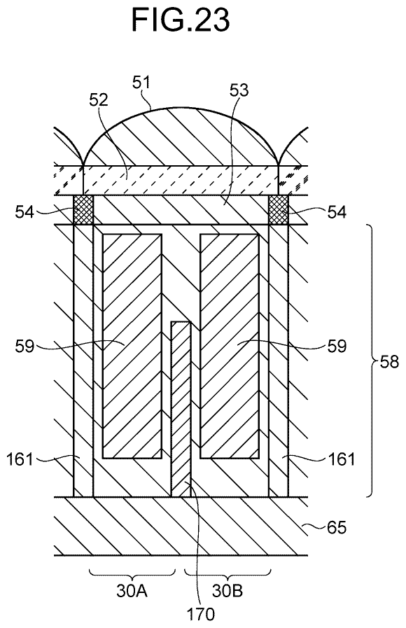

Furthermore, FIG. 22 is a cross-sectional view illustrating another cross-sectional structure example of the image plane phase difference pixel in the middle of manufacturing according to the first modification, the cross-sectional structure example in a step corresponding to that in FIG. 16. As illustrated in FIG. 22, only one side of the in-pixel separation unit 170 may be completely separated from the pixel separation unit 60 (or the film 170A). Also with this configuration, it is possible to prevent or to strongly suppress removal of the in-pixel separation unit 170 at the time of removal of the film 170A, and thus it is possible to more easily form the pixel separation unit 60 and the in-pixel separation unit 170 having different required characteristics separately.

### 1.12.2 Second Modification

FIG. 23 is a vertical cross-sectional view illustrating a schematic structure example of an image plane phase difference pixel according to a second modification, the vertical cross-sectional view illustrating a cross-sectional structure example corresponding to the cross section illustrated as an example in FIG. 7.

As illustrated in FIG. 23, in the second modification, the pixel separation unit 60 is replaced with a pixel separation unit 161 including an insulating film. That is, in the second modification, the fixed charge film 62 is omitted, and the inside of the first trench (corresponding to the groove 61) is filled with the insulating film 63.

Even with such a configuration, it is possible to enhance the separation characteristics between different-color pixels by imparting the material of the insulating film 63 with characteristics of high reflectance and high insulating properties, and thus, it is possible to achieve effects similar to those of the first embodiment described above.

### 1.12.3 Third Modification

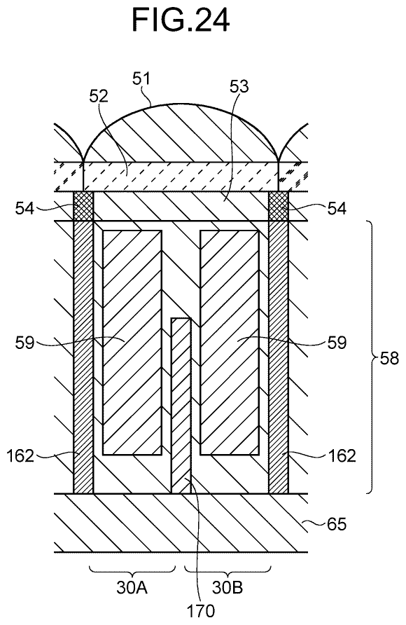

FIG. 24 is a vertical cross-sectional view illustrating a schematic structure example of an image plane phase difference pixel according to a third modification, the vertical cross-sectional view illustrating a cross-sectional structure example corresponding to the cross section illustrated as an example in FIG. 7.

As illustrated in FIG. 24, in the third modification, the pixel separation unit 60 is replaced with a pixel separation unit 162 including a light shielding film.

In a case where the pixel separation unit 162 has a single layer structure, a light shielding material such as tungsten (W) or aluminum (Al) can be used as the material thereof. However, in a case where a conductive material is used for the pixel separation unit 162, the inner surface of the first trench (groove 61) may be covered with an insulating film such as a silicon oxide film (SiO₂) or a silicon nitride film (SiN), a fixed charge film, or the like.

On the other hand, in a case where the pixel separation unit 162 has a multilayer structure, a stacked structure of aluminum (Al)/titanium (Ti)-based barrier metal, a stacked structure of aluminum (Al)/cobalt (Co), or the like may be used for the stacked structure thereof. However, as described above, in the case where a conductive material is used for the pixel separation unit 162, the inner surface of the first trench (groove 61) may be covered with an insulating film such as a silicon oxide film (SiO₂) or a silicon nitride film (SiN), a fixed charge film, or the like.

Furthermore, in a case where the pixel separation unit 162 is formed of the same material as that of the light shielding film 54 thereon, the pixel separation unit 162 and the light shielding film 54 may be formed of an integrated film.

### 1.12.4 Fourth Modification

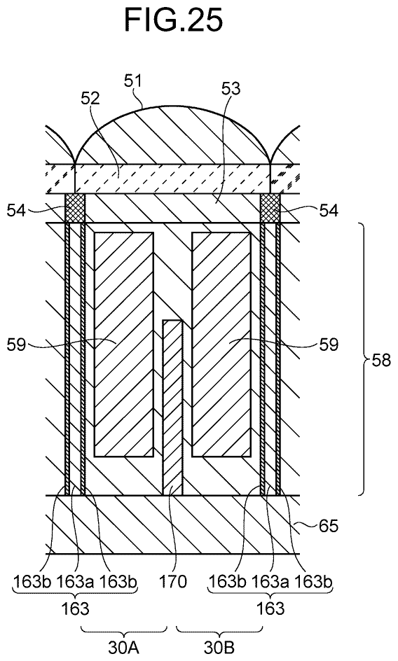

FIG. 25 is a vertical cross-sectional view illustrating a schematic structure example of an image plane phase difference pixel according to a fourth modification, the vertical cross-sectional view illustrating a cross-sectional structure example corresponding to the cross section illustrated as an example in FIG. 7.

As illustrated in FIG. 25, in the fourth modification, the pixel separation unit 60 is replaced with a pixel separation unit 163 including insulating films (silicon cover films (SCFs)) 163b having fixed charge covering the inner surface of the first trench (groove 61) and an insulating film 163a filling the inside of the first trench.

The insulating film 163a may be, for example, similar to the insulating film 63 described above.

The insulating films (SCFs) 163b have, for example, negative fixed charge due to a dipole of oxygen and can play the role of enhancing pinning of the photoelectric conversion unit PD by being in contact with the surface of the semiconductor substrate 58.

As a material of the insulating film 163b, for example, an oxide or a nitride containing at least one of hafnium (Hf), aluminum (Al), zirconium (Zr), tantalum (Ta), titanium (Ti), or the like can be used. Alternatively, it is also possible to use an oxide or a nitride containing at least one of lanthanum (La), cerium (Ce), neodymium, promethium (Pm), samarium (Sm), europium (Eu), gadolinium (Gd), terbium (Tb), dysprosium (Dy), holmium (Ho), thulium (Tm), ytterbium (Yb), lutetium (Lu), yttrium (Y), or the like. In addition, the insulating films 163b may be made of hafnium oxynitride or aluminum oxynitride. Furthermore, silicon or nitrogen of an amount that does not impair the insulating properties may be added to the insulating film 163b. Accordingly, heat resistance and the like can be improved.

### 1.12.5 Fifth Modification

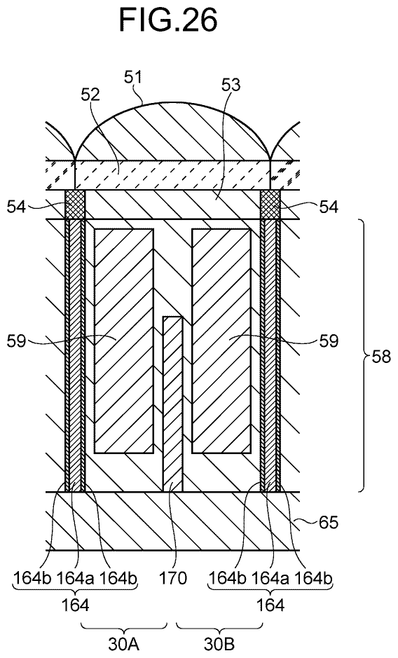

FIG. 26 is a vertical cross-sectional view illustrating a schematic structure example of an image plane phase difference pixel according to a fifth modification, the vertical cross-sectional view illustrating a cross-sectional structure example corresponding to the cross section illustrated as an example in FIG. 7.

As illustrated in FIG. 26, in the fifth modification, the pixel separation unit 60 is replaced with a pixel separation unit 164 including insulating films (SCFs) 164b having fixed charge covering the inner surface of the first trench (groove 61) and a light shielding film 164a filling the inside of the first trench.

The insulating film 164b may be, for example, similar to the insulating film 163b according to the fourth embodiment.

The light shielding film 164a may be, for example, a single-layer film of tungsten (W), aluminum (Al), or the like, a stacked structure of aluminum (Al)/titanium (Ti)-based barrier metals, or a multilayer film of aluminum (Al)/cobalt (Co).

### 1.12.6 Sixth Modification

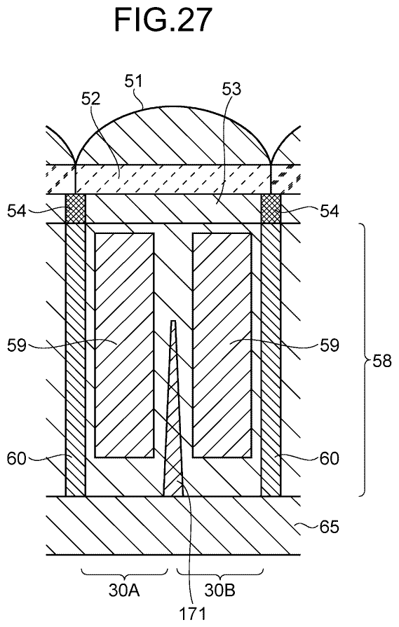

FIG. 27 is a vertical cross-sectional view illustrating a schematic structure example of an image plane phase difference pixel according to a sixth modification, the vertical cross-sectional view illustrating a cross-sectional structure example corresponding to the cross section illustrated as an example in FIG. 7.

In the first embodiment and the modifications thereof described above, for example, as illustrated in FIG. 6 as an example, the in-pixel separation unit 170 has a shape in which the width of the upper end and the width of the lower end are substantially equal to each other. That is, the case where the cross-sectional shape of the in-pixel separation unit 170 on the vertical plane (corresponding to the D-D plane) parallel to the array direction of the pixel 30A and the pixel 30B is rectangular has been described as an example.

Meanwhile, in the sixth modification, as illustrated in FIG. 27, an in-pixel separation unit 171 may have a shape in which the width of the upper end is narrower than the width of the lower end, namely, a shape in which the cross section of the in-pixel separation unit 170 on the vertical plane (corresponding to the D-D plane) parallel to the array direction of the pixels 30A and 30B is a trapezoid or a triangle elongated in the vertical direction.

As described above, by narrowing the width of the upper end of the in-pixel separation unit 171, the amount of light reflected by the upper end and leaking from the pixels 30 can be reduced, and thus it is possible to suppress a decrease in the light receiving sensitivity.

### 2. Second Embodiment

Next, a second embodiment of the present disclosure will be described in detail with reference to the drawings. Note that, in the following description, redundant description for similar structure, operation, manufacturing method, and effects to those of the first embodiment or the modifications thereof is omitted by citing those.

As described in the first embodiment and the modifications thereof, in a case where individual image plane phase difference pixels (different-color pixels) are optically and electrically separated by a penetrating structure, and the inside of one image plane phase difference pixel is electrically separated by a non-penetrating structure capable of forming an overflow path, characteristics of high reflectance and high insulating properties are required for the separation material (namely, the material of the pixel separation unit 60) for separation between different-color pixels, whereas characteristics of low reflectance, low insulating properties, and non-photoelectric conversion properties are required for the separation material (namely, the material of the in-pixel separation unit 170) for separation between the same-color pixels.

Therefore, in the present embodiment, some examples will be given on the constituent materials of the pixel separation unit 60 and the in-pixel separation unit 170. Note that the structure examples of the solid state imaging device 10, the image plane phase difference pixel, and the pixels may be similar to the structure examples described as examples in the first embodiment or the modifications thereof described above.

### 2.1 First Example

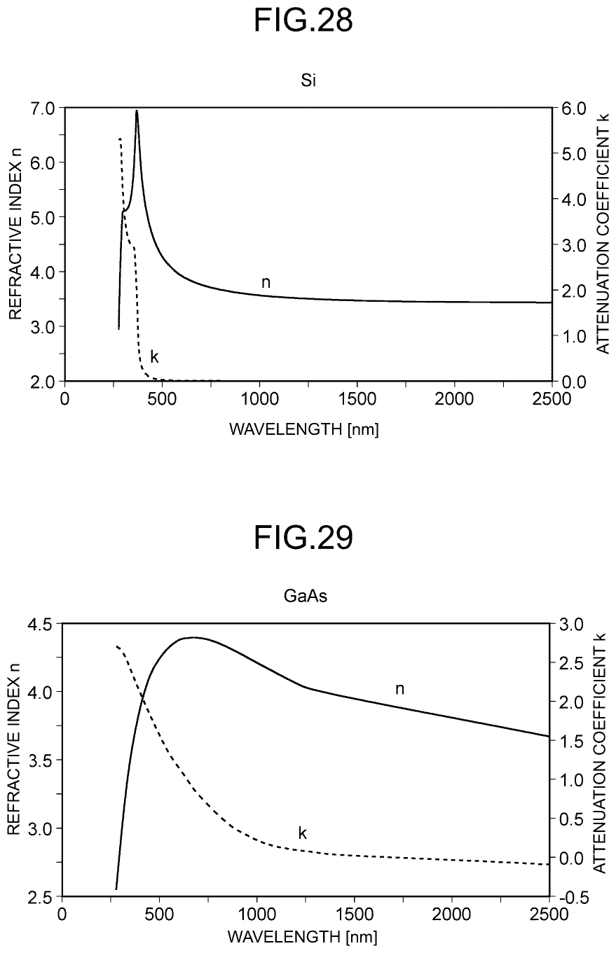

FIG. 28 is a graph illustrating wavelength dependency of the refractive index n and the band gap energy k of silicon (Si). FIG. 29 is a graph illustrating wavelength dependency of the refractive index n and the band gap energy k of gallium arsenide (GaAs).

In order for the in-pixel separation unit 170 that separates two pixels 30A and 30B constituting one image plane phase difference pixel to have low reflectance, low insulating properties, and non-photoelectric conversion properties, a material having a refractive index n close to that of the constituent material of the semiconductor substrate 58 and having wide band gap energy is desirably used as a material included in the in-pixel separation unit 170.

Incidentally, for example, in a case where the semiconductor substrate 58 is a silicon substrate, as illustrated in FIG. 28, the refractive index n of Si for light having a wavelength of 500 nm is equal to or greater than 4, and the band gap energy k for light having the wavelength of 500 nm is about 1.12 electronvolts (eV).

Therefore, as a first example, GaAs is presented as a constituent material of the in-pixel separation unit 170. As illustrated in FIG. 29, the refractive index n of GaAs for light having the wavelength of 500 nm is equal to or greater than 4, which is equivalent to that of Si (equal to or greater than 4), and the band gap energy k for light having the wavelength of 500 nm is about 1.43 eV, which is larger than that of Si (about 1.12 ev).

Therefore, by using GaAs as the constituent material of the in-pixel separation unit 170, it is possible to suppress photoelectric conversion in the in-pixel separation unit 170 while suppressing reflection at the interface between a semiconductor substrate 50 and the in-pixel separation unit 170. Since GaAs is a compound semiconductor, it is also possible to achieve low insulating properties.

### 2.2 Second Example

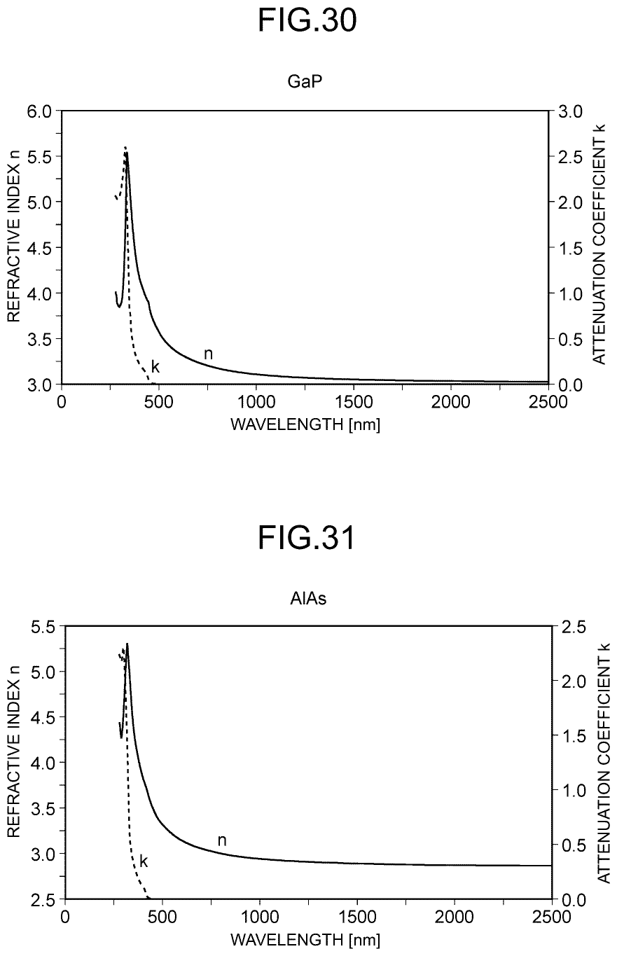

As a second example, gallium phosphide (GaP) is presented as a constituent material of the in-pixel separation unit 170. FIG. 30 is a graph illustrating wavelength dependency of the refractive index n and the band gap energy k of gallium phosphide (GaP).

As illustrated in FIG. 30, the refractive index n of GaP for light having the wavelength of 500 nm is about 3.5 which is slightly lower than that of Si (equal to or greater than 4), and the band gap energy k for light having the wavelength of 500 nm is about 2.3 eV which is larger than that of Si (about 1.12 eV).

Therefore, by using GaP as the constituent material of the in-pixel separation unit 170, it is possible to suppress photoelectric conversion in the in-pixel separation unit 170 while suppressing reflection at the interface between the semiconductor substrate 50 and the in-pixel separation unit 170, similarly to the above-described example. Since GaP is a compound semiconductor, it is also possible to achieve low insulating properties.

### 2.3 Third Example

As a third example, aluminum arsenide (AlAs) is presented as a constituent material of the in-pixel separation unit 170. FIG. 31 is a graph illustrating wavelength dependency of the refractive index n and the band gap energy k of aluminum arsenide (AlAs).

As illustrated in FIG. 31, the refractive index n of AlAs for light having the wavelength of 500 nm is about 3.25 which is slightly lower than that of Si (equal to or greater than 4), and the band gap energy k for light having the wavelength of 500 nm is about 2.12 eV which is larger than that of Si (about 1.12 eV).

Therefore, by using GaP as the constituent material of the in-pixel separation unit 170, it is possible to suppress photoelectric conversion in the in-pixel separation unit 170 while suppressing reflection at the interface between the semiconductor substrate 50 and the in-pixel separation unit 170, similarly to the above-described example. Since AlAs is a semiconductor material, it is also possible to achieve low insulating properties.

### 2.4 Fourth Example

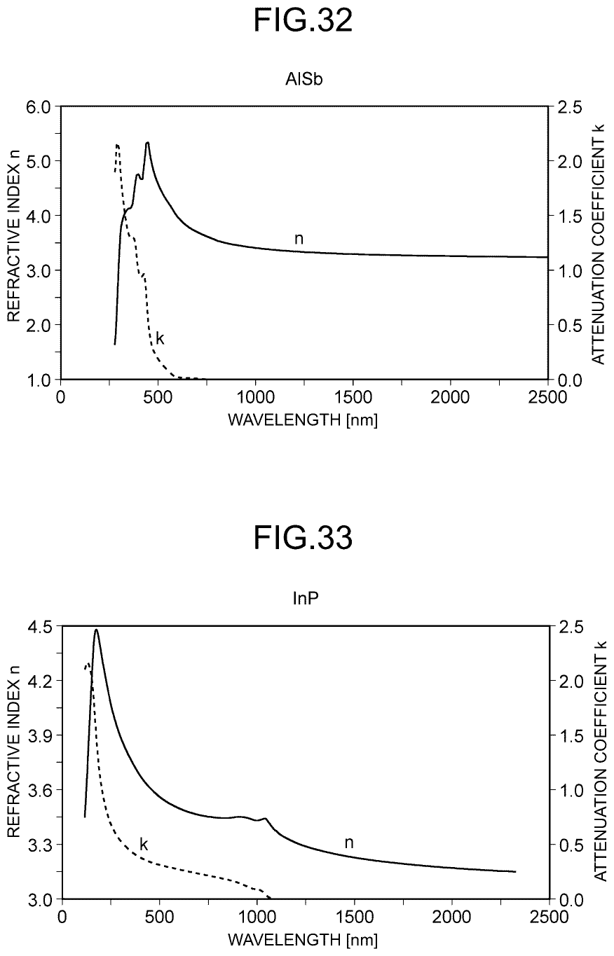

As a fourth example, aluminum antimonide (AlSb) is presented as a constituent material of the in-pixel separation unit 170. FIG. 32 is a graph illustrating wavelength dependency of the refractive index n and the band gap energy k of aluminum antimonide (AlSb).

As illustrated in FIG. 32, the refractive index n of AlSb for light having the wavelength of 500 nm is equal to or greater than 4, which is about the same as that of Si (equal to or greater than 4), and the band gap energy k for light having the wavelength of 500 nm is about 1.58 eV, which is larger than that of Si (about 1.12 eV).

Therefore, by using GaP as the constituent material of the in-pixel separation unit 170, it is possible to suppress photoelectric conversion in the in-pixel separation unit 170 while suppressing reflection at the interface between the semiconductor substrate 50 and the in-pixel separation unit 170, similarly to the above-described examples. Since AlSb is a group III-V semiconductor, it is also possible to achieve low insulating properties.

### 2.5 Fifth Example

As a fifth example, indium phosphide (InP) is presented as a constituent material of the in-pixel separation unit 170. FIG. 33 is a graph illustrating wavelength dependency of the refractive index n and the band gap energy k of indium phosphide (InP).

As illustrated in FIG. 33, the refractive index n of InP for light having the wavelength of 500 nm is 3.7 which is slightly lower than that of Si (equal to or greater than 4), and the band gap energy k for light having the wavelength of 500 nm is about 1.29 eV which is larger than that of Si (about 1.12 ev).

Therefore, by using InP as the constituent material of the in-pixel separation unit 170, it is possible to suppress photoelectric conversion in the in-pixel separation unit 170 while suppressing reflection at the interface between the semiconductor substrate 50 and the in-pixel separation unit 170, similarly to the above-described examples. Since InP is a III-V group semiconductor, it is also possible to achieve low insulating properties.

### 2.6 Sixth Example

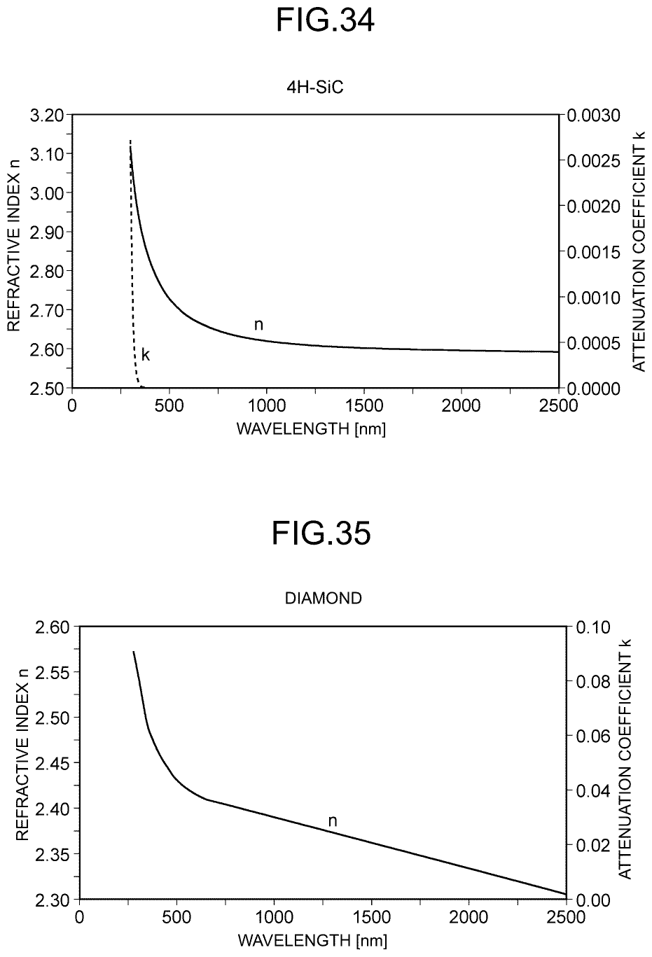

As a sixth example, hexagonal silicon carbide (4H-SiC) is presented as a constituent material of the in-pixel separation unit 170. FIG. 34 is a graph illustrating wavelength dependency of the refractive index n and the band gap energy k of hexagonal silicon carbide (4H-SiC).

As illustrated in FIG. 34, the refractive index n of 4H-SiC for light having the wavelength of 500 nm is 2.7, which is lower than that of Si (equal to or greater than 4); however, the band gap energy k for light having the wavelength of 500 nm is about 3.26 eV, which is much higher than that of Si (about 1.12 eV).

Therefore, by using 4H-SiC as the constituent material of the in-pixel separation unit 170, it is possible to significantly suppress photoelectric conversion in the in-pixel separation unit 170 while suppressing an increase in reflection at the interface between the semiconductor substrate 50 and the in-pixel separation unit 170. Note that 4H-SiC is a material having semiconductivity.

Instead of 4H-SiC, it is also possible to use hexagonal silicon carbide (6H-SiC) having a band gap energy k of about 3.02 eV or cubic silicon carbide (3C-SiC) having a band gap energy k of 2.23 eV for light having the wavelength of 500 nm.

### 2.7 Seventh Example

As a seventh example, diamond is presented as a constituent material of the in-pixel separation unit 170. FIG. 35 is a graph illustrating wavelength dependency of the refractive index n of diamond.

As illustrated in FIG. 35, the refractive index n of diamond for light having the wavelength of 500 nm is 2.4, which is lower than that of Si (equal to or greater than 4); however, the band gap energy k for light having the wavelength of 500 nm is about 5.47 eV, which is much higher than that of Si (about 1.12 eV).

Therefore, by using diamond as the constituent material of the in-pixel separation unit 170, as in the sixth example, it is possible to significantly suppress photoelectric conversion in the in-pixel separation unit 170 while suppressing an increase in reflection at the interface between the semiconductor substrate 50 and the in-pixel separation unit 170. Note that diamond can acquire conductivity by being doped with an impurity such as boron (B).

### 2.8 Eighth Example

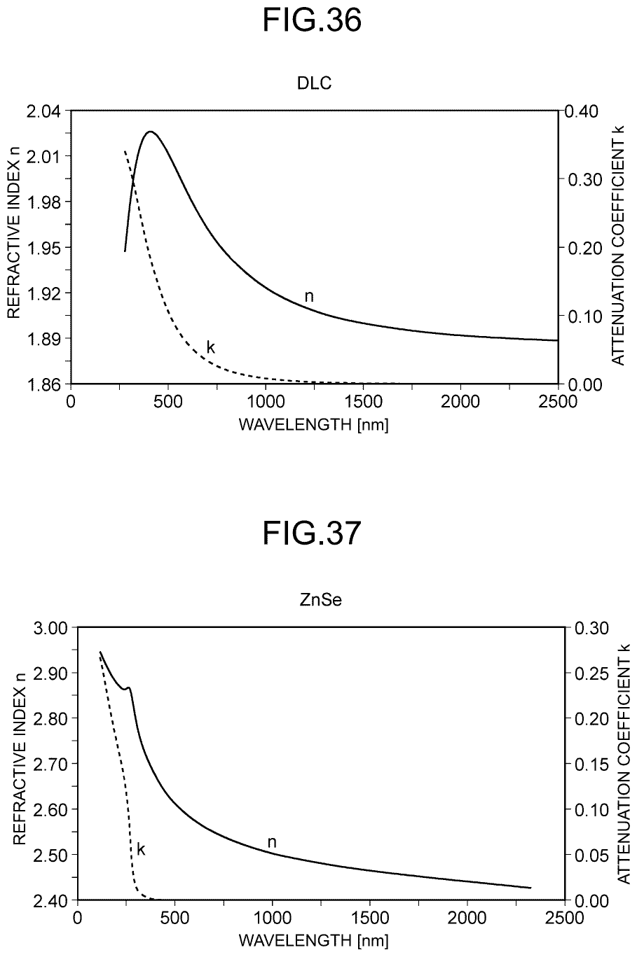

As an eighth example, diamond-like carbon (DLC) is presented as a constituent material of the in-pixel separation unit 170. FIG. 36 is a graph illustrating wavelength dependency of the refractive index n and the band gap energy k of DLC.

As illustrated in FIG. 36, the refractive index n of DLC for light having the wavelength of 500 nm is 2.01, which is lower than that of Si (equal to or greater than 4); however, the band gap energy k for light having the wavelength of 500 nm varies in the range of 0.8 eV to 4.0 eV by controlling a ratio of sp2/sp3, and the band gap energy k increases as sp3 increases.

Therefore, by using DLC with an adjusted sp2/sp3 ratio as a constituent material of the in-pixel separation unit 170, as in the sixth and seventh examples, it is possible to significantly suppress photoelectric conversion in the in-pixel separation unit 170 while suppressing an increase in reflection at the interface between the semiconductor substrate 50 and the in-pixel separation unit 170. Note that, like diamond, DLC can acquire conductivity by being doped with an impurity such as boron (B).

### 2.9 Ninth Example

As a ninth example, zinc selenide (ZnSe) is presented as a constituent material of the in-pixel separation unit 170. FIG. 37 is a graph illustrating wavelength dependency of the refractive index n and the band gap energy k of zinc selenide (ZnSe).

As illustrated in FIG. 37, the refractive index n of ZnSe for light having the wavelength of 500 nm is 2.6, which is lower than that of Si (equal to or greater than 4); however, the band gap energy k for light having the wavelength of 500 nm is about 2.7 eV, which is higher than that of Si (about 1.12 eV).

Therefore, by using diamond as the constituent material of the in-pixel separation unit 170, as in the sixth to eighth examples, it is possible to significantly suppress photoelectric conversion in the in-pixel separation unit 170 while suppressing an increase in reflection at the interface between the semiconductor substrate 50 and the in-pixel separation unit 170. Note that ZnSe is intrinsic semiconductor.

### 2.10 Other Examples

In addition to the materials described above, a ternary compound semiconductor such as aluminum antimonide arsenide (AlSbAs), aluminum antimonide phosphide (AlSbP), indium aluminum phosphide (AlInP), gallium arsenide phosphide (GaAsP), indium gallium phosphide (InGaP), or aluminum gallium arsenide (GaAlAs) can be used as the material of the in-pixel separation unit 170.

### 2.11 Summary

As described above, by using a material having a refractive index higher than or equal to (or may be lower than depending on the case) the constituent material of the semiconductor substrate 58 and having band gap energy larger than that of the constituent material of the semiconductor substrate 58 as the separation material (namely, the material of the in-pixel separation unit 170) for separation between same-color pixels, it is possible to implement the solid state imaging device 10 and the electronic apparatus in which a low refractive index (namely, high reflectance) and high insulating properties are achieved between different-color pixels desired to be optically separated and a high refractive index (namely, low reflectance), high insulating properties, and non-photoelectric conversion properties are achieved between same-color pixels desired to be electrically separated without being optically separated.

Note that the described as an example materials including those of the first embodiment may be used in combination as appropriate. Other configurations, operations, manufacturing method, and effects may be similar to those of the above-described embodiment or modifications thereof, and thus detailed description is omitted here.

### 3. Third Embodiment

Next, a third embodiment of the present disclosure will be described in detail with reference to the drawings. Note that, in the following description, redundant description for similar structure, operation, manufacturing method, and effects to those of the first and second embodiments or the modifications thereof is omitted by citing those.

In the above-described embodiment and the modifications thereof, the case where the pixel separation unit 60 and the in-pixel separation unit 170 are separately formed depending on characteristics required for each of them has been described as an example. Meanwhile, in the third embodiment, description will be given with an example on a case of suppressing a decrease in the light receiving sensitivity of the solid state imaging device by suppressing a decrease in the quantum efficiency Qs of the image plane phase difference pixel by improving the performance of the in-pixel separation unit.

In a case of manufacturing a pixel with in-pixel separation such as the image plane phase difference pixel, it is conceivable to provide an overflow path for releasing carriers to another pixel when one pixel is saturated as in the above-described embodiment and the modifications thereof. In this case, an electrically separated region and an electrically connected region are both present in the in-pixel separation unit separating the left pixel and the right pixel, and thus it is difficult to manufacture or to control the in-pixel separation unit.

For example, JP 2018-201015 A proposes a method of separating an in-pixel separation unit by embedding an oxide film or a metal in order to improve characteristics of the in-pixel separation unit. In addition, JP 2019-9425 A proposes a method of controlling characteristics of an in-pixel separation unit by the impurity concentration with an intercolor path.

However, in the conventional methods, since the manufacturing process of the in-pixel separation unit is complicated, the number of ion implantation steps to a photoelectric conversion layer increases, and there is a concern about increased noise due to defect formation. There are also concerns such as variations in the line width at the time of ion implantation or a decrease or variation in Qs due to impurity diffusion. Furthermore, since a region in which an N-type dopant is doped at a high concentration for a P-type semiconductor region is present in the vicinity of a transfer transistor, there is also a problem of deteriorated transfer efficiency or increased noise as the pixels are miniaturized.

In addition, as disclosed in JP 2018-201015 A, a physical in-pixel separation structure by embedding an oxide film or a metal is also possible in addition to electrical separation by reversed polarity; however, in this structure, there is a concern about a decrease in the quantum efficiency QE due to a decrease in the photoelectric conversion region in the vicinity of a light condensing unit.

Meanwhile, the method disclosed in JP 2019-9425 A optimizes a potential structure between a left pixel and a right pixel by controlling the impurity concentration with an overflow path. However, it is conceivable that it is difficult to perform process control when forming an in-pixel separation unit as the pixels are miniaturized.

As described above, in the conventional methods, there may be problems as described as an example below.
(1) Increased noise due to defect formation by implantation inside pixels
(2) Decrease in Qs and generation of variation due to variation in line width and impurity diffusion
(3) Deteriorated transfer efficiency or increased noise due to formation of high-concentration p-n doped back regions in the vicinity of transfer gates
(4) In the case of physical separation, decreased photoelectric conversion efficiency in the vicinity of light condensing units

Therefore, in the present embodiment, by forming in-pixel separation with a graded epitaxial (graded-epi) layer having a polarity opposite to that of the charge generated in the photoelectric conversion region, an overflow path electrically connecting the left and right pixels is formed. As a result, no ion implantation step is required to create the in-pixel separation unit, and thus it is possible to avoid or to suppress the problems of (1) to (3). In addition, since the graded-epi layer can also function as a photoelectric conversion region, the problem of (4) can also be suppressed or avoided.

### 3.1 Cross-Sectional Structure Example of Image Plane Phase Difference Pixel

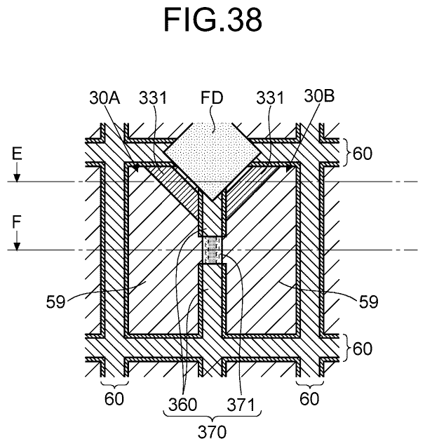

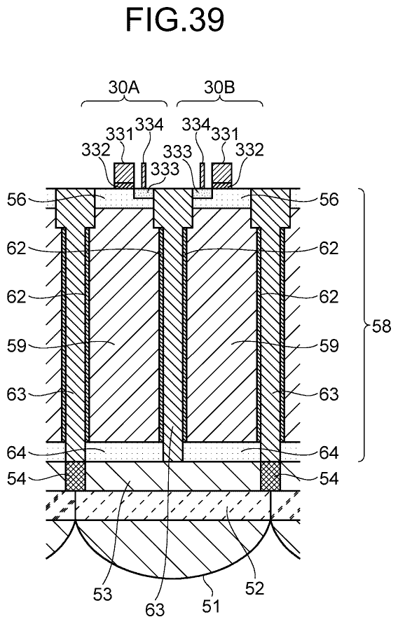

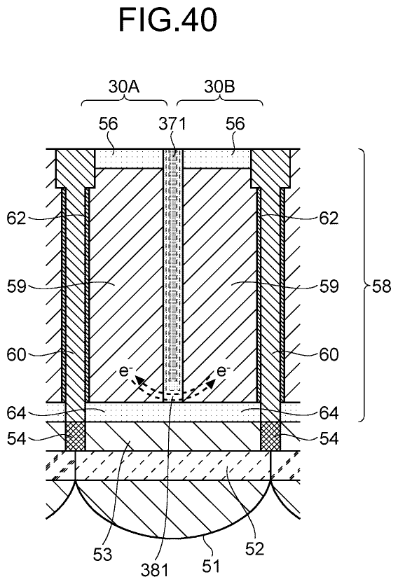

FIG. 38 is a top view illustrating a planar structure example of an image plane phase difference pixel according to the present embodiment. FIG. 39 is a vertical cross-sectional view illustrating a structure example of a cross section taken along line E-E in FIG. 38. FIG. 40 is a vertical cross-sectional view illustrating a structure example of a cross section taken along line F-F in FIG. 38.

As illustrated in FIGS. 38 to 40, in the present embodiment, an in-pixel separation unit 370, which divides an image plane phase difference pixel region partitioned by the pixel separation unit 60 into two, for example, rectangular regions, includes a first separation unit 360 and a second separation unit 371.

The first separation unit 360 is, for example, a structural unit continuous from the pixel separation unit 60 and may have a layer structure similar to that of the pixel separation unit 69.

The second separation unit 371 is disposed, for example, substantially at the center of the in-pixel separation unit 370, which divides the image plane phase difference pixel region, in such a manner as to divide the first separation unit 360 in the vertical direction.

In a case where an overflow path is formed at a certain position in the vertical direction in the second separation unit 371, the impurity concentration of the second separation unit 371 in a region other than an overflow path 381 may be adjusted in such a manner as to increase in opposite polarity as it is closer to the center of the second separation unit 371 in the horizontal direction and to increase in opposite polarity as it is separated away from the overflow path 381 in the vertical direction, for example. In other words, the impurity concentration profile of the second separation unit 371 may be adjusted such that, for example, the potential barrier becomes higher as it is closer to the center of the second separation unit 371 in the horizontal direction and that the potential barrier becomes higher as it is separated away from the overflow path 381 in the vertical direction. Furthermore, in the region where the overflow path 381 is formed, the impurity concentration may be adjusted to be substantially uniform in the horizontal direction and the vertical direction.

The second separation unit 371 having such an impurity concentration profile may be configured using, for example, a graded-epi layer adjusted such that the impurity concentration increases as it is closer to the inner side of the second separation unit 371. For example, in a case where a silicon substrate containing an N-type impurity is used as the semiconductor substrate 58, the graded-epi layer may be a semiconductor layer (epitaxial layer) containing P-type impurity. By forming a part of the in-pixel separation unit 370 with the graded-epi layer, it is possible to achieve both optical and/or electrical separation between a right pixel 30A and a left pixel 30B and formation (namely, reduction of the difference in the light receiving sensitivity between the right and left pixels) of the overflow path 381 when one of the pixels 30A and 30B is saturated.

As the material of the second separation unit 371, a material having high potential energy for a read carrier may be used in relation to the constituent material of a photoelectric conversion unit PD. For example, a group IV semiconductor including at least one of carbon (C), silicon (Si), germanium (Ge), or tin (Sn), a group III-V semiconductor including at least two of boron (B), aluminum (Al), gallium (Ga), indium (In), nitrogen (N), phosphorus (P), arsenic (As), and antimony (Sb), or the like may be used. However, it is not limited thereto, and various semiconductor materials can be used.

A transfer transistor 31 of each of the pixels 30A and 30B may include, for example, a diffusion region 333 (source/drain region) included at a corner where the pixel separation unit 60 and the in-pixel separation unit 370 intersect in each pixel region and provided on an element formation surface side surface of the semiconductor substrate 50 and a gate insulating film 332 and a gate electrode 331 provided on the element formation surface. Note that the other source/drain region of the transfer transistor 31 may include the cathode of the photoelectric conversion unit PD.

Furthermore, in a case where the pixels 30A and 30B share one floating diffusion region FD, the floating diffusion region FD may be disposed at a position covering corners where the pixel separation unit 60 and the in-pixel separation unit 370 intersect each other, the corners where the transfer transistors 31 of the pixels are arranged. The floating diffusion region FD may be electrically connected with a diffusion region 333 of a transfer transistor 31 of each of the pixels 30A and 30B via a via contact 334.

With the structure as described above, it is possible to suppress defects in the vicinity of the region where the in-pixel separation unit 370 is formed as compared with the case where the left and right pixels are separated by ion implantation, and thus, it is possible to suppress noise. Moreover, since the width of the in-pixel separation unit 370 in the horizontal direction (direction parallel to the element formation surface) is easily controlled, it is possible to suppress a decrease and variation in the saturation signal amount Qs. Furthermore, since a distance from the overflow path 381 (namely, the second separation unit 371) to the transfer transistor 31 can be secured, the impurity concentration in portions close to the transfer transistors 31 can be suppressed to be low. As a result, it is possible to suppress deterioration of transfer efficiency or increased noise due to miniaturization. In addition, since at least a part of the in-pixel separation unit 370 (corresponding to the second separation unit 371) is made of a semiconductor material, it is possible to suppress kicking of incident light in the vicinity of the light condensing unit or a decrease in photoelectric conversion efficiency.

### 3.2 Manufacturing Method

Next, a manufacturing method of the solid state imaging device 10 according to the present embodiment will be described. Note that, in the following description, a case where the transfer transistor 31 among the transistors (Transfer transistor 31, reset transistor 32, amplification transistor 33, and selection transistor 34) included in the pixel circuit for reading out charge from the photoelectric conversion unit PD is disposed in the same light receiving chip 41 as the photoelectric conversion unit PD is disposed will be described as an example; however, it is not limited thereto, and at least one transistor other than the transfer transistor 31 may also be disposed in the light receiving chip 41.

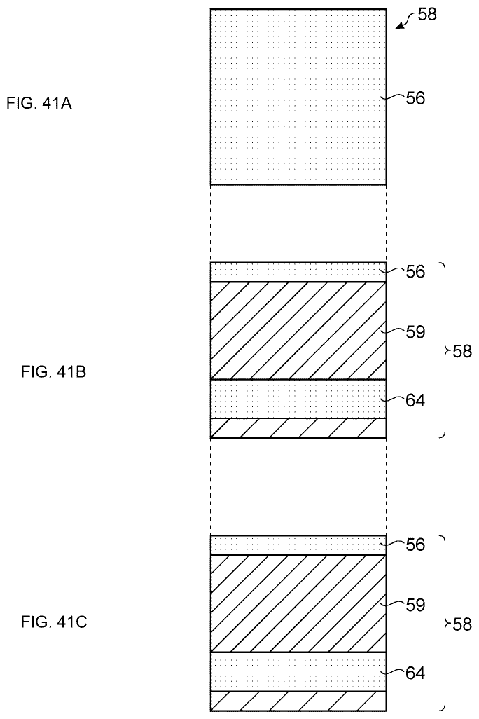

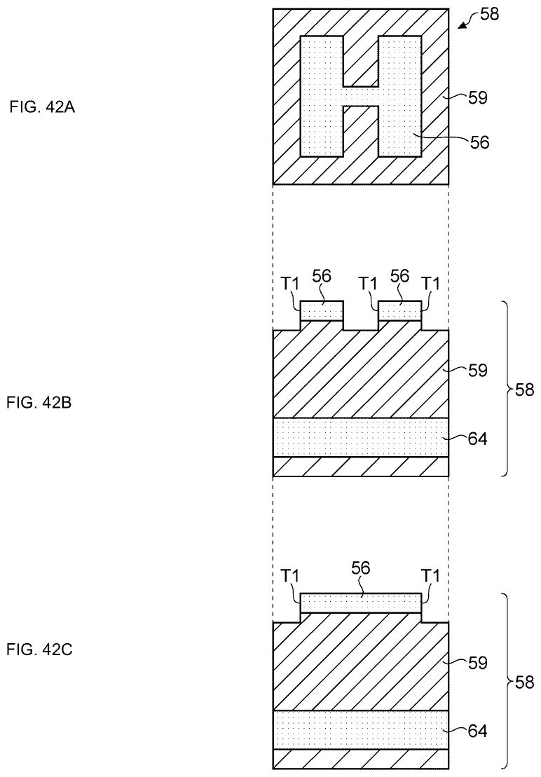

FIGS. 41 to 47 are process cross-sectional views illustrating a manufacturing method of the solid state imaging device according to the embodiment. Note that, in FIGS. 41 to 47, (A) is a top view illustrating a planar structure example of the image plane phase difference pixel corresponding to FIG. 38, (B) is a vertical cross-sectional view illustrating a structure example of an E-E cross section corresponding to FIG. 39, and (C) is a vertical cross-sectional view illustrating a structure example of an F-F cross section corresponding to FIG. 40. However, for convenience of description, the scale, the size, and the like of each layer illustrated in FIGS. 41 to 47 are different from the scale, the size, and the like of each layer illustrated in FIGS. 38 to 40.

In the present manufacturing method, first, as illustrated in FIG. 41, by implanting a P-type dopant and an N-type dopant into the prepared semiconductor substrate 58 as appropriate, P-type semiconductor regions 56 and 64 are formed on the front surface side and the back surface side of the semiconductor substrate 58, respectively, and an N-type semiconductor region 59 is formed in a region sandwiched between the P-type semiconductor regions 56 and 64.

Next, as illustrated in FIG. 42, for example, a trench (shallow trench isolation (STI)) T1 that is shallow to the extent of exposing an upper layer of the N-type semiconductor region 59 is formed in a region where the pixel separation unit 60 and the first separation unit 360 of the in-pixel separation unit 370 are formed on the front surface side of the semiconductor substrate 58 by using lithography technology.

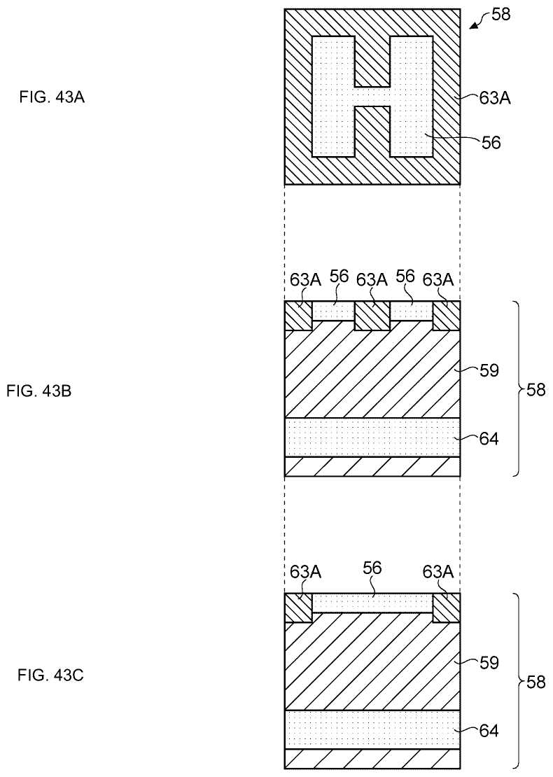

Next, as illustrated in FIG. 43, an insulating material is filled in the trench T1 formed on the front surface side of the semiconductor substrate 58 by using a film forming method such as a CVD method or sputtering, whereby an insulating film 63A to be a part of the insulating film 63 is formed in the trench T1.

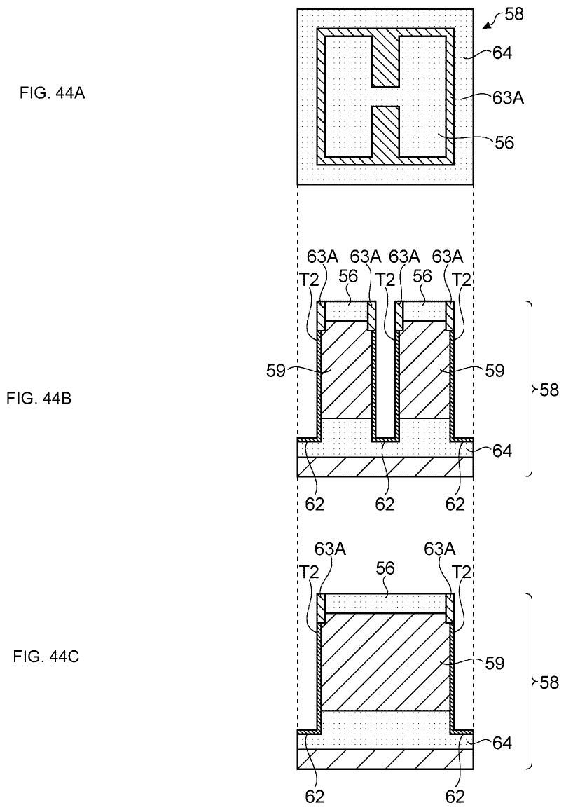

Next, as illustrated in FIG. 44, a trench T2 deep enough to expose the P-type semiconductor region 64 on the back surface side of the semiconductor substrate 58 is formed in a region (namely, the region where the insulating film 63A is formed) where the pixel separation unit 60 and the first separation unit 360 of the in-pixel separation unit 370 are formed on the front surface side of the semiconductor substrate 58 by using, for example, lithography technology. Incidentally, anisotropic dry etching such as reactive ion etching (RIE) may be used for deep etching of the semiconductor substrate 58.

Subsequently, the fixed charge film 62 is formed on the front surface of the semiconductor substrate 58 exposed to the inner surface and the bottom surface of the trench T2 by using ion implantation technology such as plasma assisted doping (PLAD).

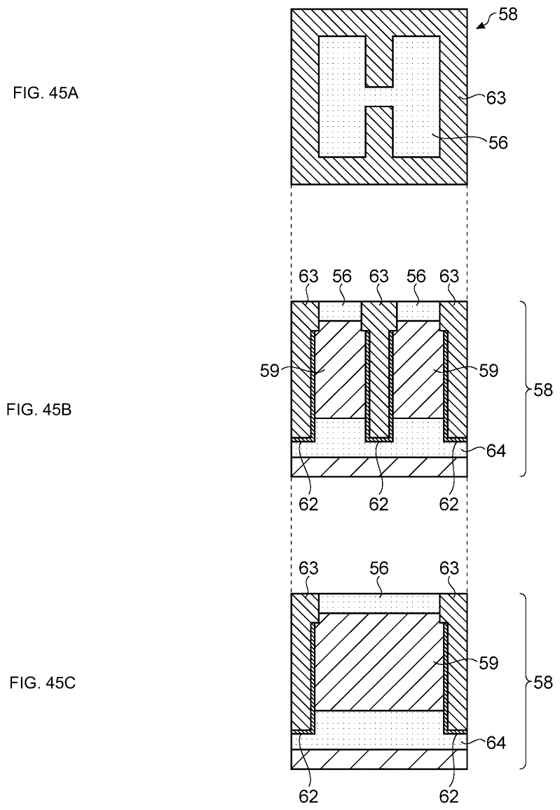

Next, as illustrated in FIG. 45, an insulating material is filled in the trench 12 in which the fixed charge film 62 is formed on the inner surface and the bottom surface by using a film forming method such as a CVD method or sputtering, thereby forming the insulating film 63 in the trench T2. As a result, the pixel separation unit 60 and the first separation unit 360 are formed.

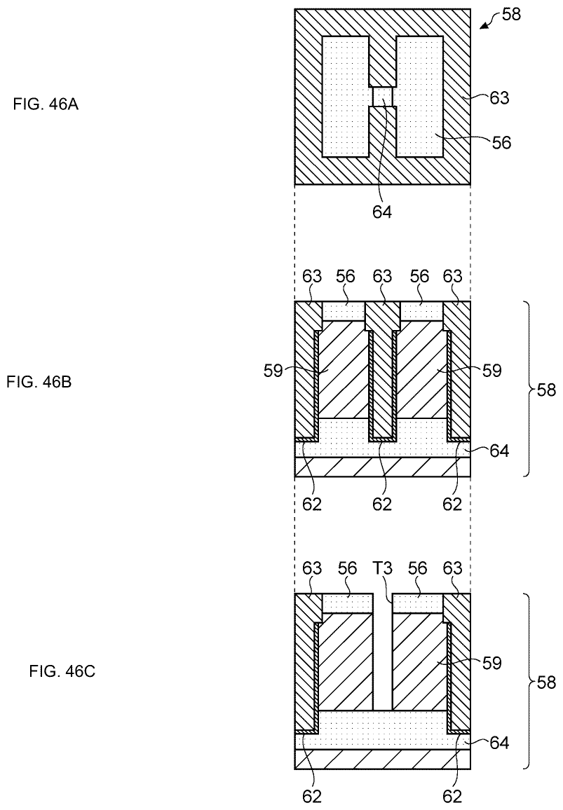

Next, as illustrated in FIG. 46, a trench T3 deep enough to expose the front surface of the P-type semiconductor region 64 on the back surface side of the semiconductor substrate 58 is formed in a region where the second separation unit 371 is formed on the front surface side of the semiconductor substrate 58 by using, for example, lithography technology. Incidentally, anisotropic dry etching such as RIE may be used for deep etching of the semiconductor substrate 58.

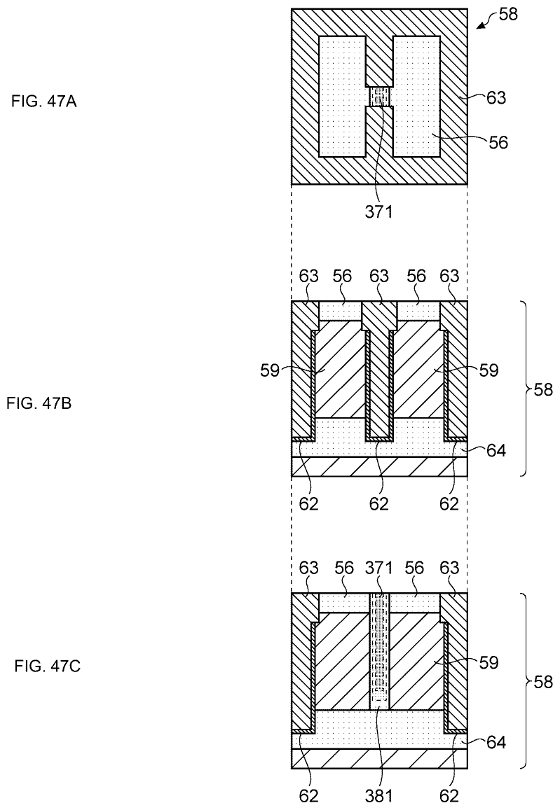

Next, as illustrated in FIG. 47, for example, by using a film forming method such as graded epitaxial technique capable of controlling the impurity concentration in a stepwise manner, the second separation unit 371, including the graded-epi layer in which the impurity concentration is adjusted such that the opposite polarity increases as it is closer to the inner side, is formed. At this point, the impurity concentration on the back surface side of the semiconductor substrate 58 in the second separation unit 371 is reduced, whereby this region functions as the overflow path 381.

Then, circuit elements such as the transfer transistors 31 and a wiring layer 65 are formed on the front surface side of the semiconductor substrate 58, and then a light shielding film 54, a planarization film 53, a color filter 52, and an on-chip lens 51 are sequentially formed on the back surface side of the semiconductor substrate 58, whereby the solid state imaging device 10 including the image plane phase difference pixel having the cross-sectional structure illustrated in FIGS. 38 to 40 can be manufactured.

In the above manufacturing process, the order of the steps described with reference to FIGS. 44 and 45 and the steps described with reference to FIGS. 46 and 47 may be switched.

### 3.3 Modification of Image Plane Phase Difference Pixel Structure

Next, modifications of the image plane phase difference pixel structure according to the present embodiment will be described with some examples.

### 3.3.1 First Modification

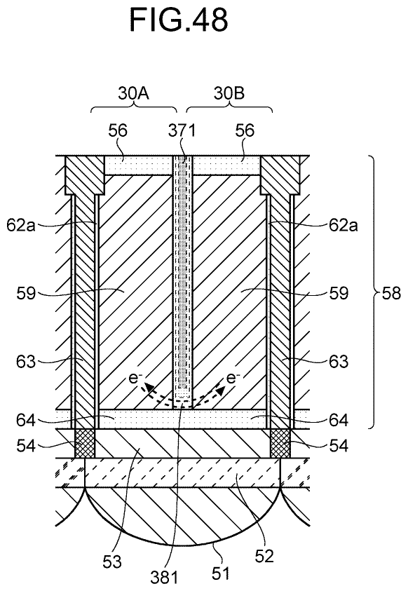

FIG. 48 is a vertical cross-sectional view illustrating a cross-sectional structure example of an image plane phase difference pixel according to a first modification. As illustrated in FIG. 48, in the first modification, the fixed charge film 62 in the pixel separation unit 60 is replaced with a diffusion region 62a formed by implanting an ion having a polarity opposite to the charge generated in the photoelectric conversion unit PD. In this manner, the potential around the photoelectric conversion unit PD can be adjusted also by using the diffusion region 62a formed by ion implantation, solid phase diffusion, or the like instead of the fixed charge film 62 formed using PLAD, for example.

### 3.3.2 Second Modification

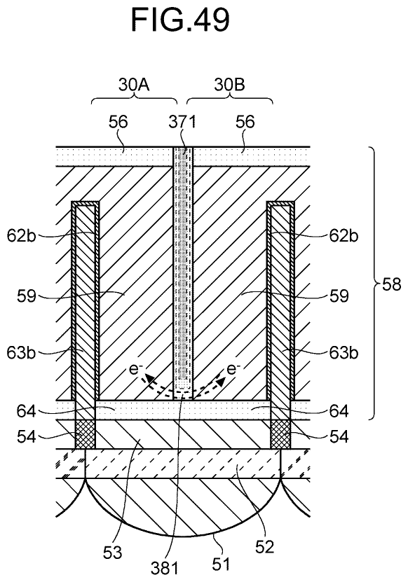

FIG. 49 is a vertical cross-sectional view illustrating a cross-sectional structure example of an image plane phase difference pixel according to a second modification. As illustrated in FIG. 49, in the second modification, a pixel separation unit 60 having an RDTI structure is used instead of the pixel separation unit 60 having the FTI structure. The pixel separation unit 60 having the RDTI structure has a structure in which a trench dug from the back surface (light incident surface) side of the semiconductor substrate 58 is filled with an insulating film 63b, and the periphery of the insulating film 63b is covered with a fixed charge film 62b. As described above, various structures such as an FTI structure and an RDTI structure may be adopted as the structure of the pixel separation unit 60 (and the first separation unit 360) that optically and electrically separates the image plane phase difference pixel regions (and portions of the pixel regions) from each other.

### 3.3.3 Third Modification

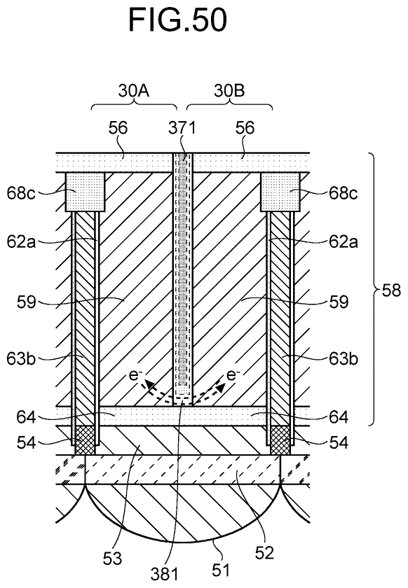

FIG. 50 is a vertical cross-sectional view illustrating a cross-sectional structure example of an image plane phase difference pixel according to a third modification. As illustrated in FIG. 50, in the third modification, similarly to the second modification, a pixel separation unit 60 having an RDTI structure is used instead of the pixel separation unit 60 having an FTI structure. In addition, in the third modification, the fixed charge film 62b covering the insulating film 63b is formed by ion implantation or replaced with a diffusion region 62c, and a diffusion region 68c is disposed between the top surface of the insulating film 63b and the P-type semiconductor region 56. As described above, in the case where the pixel separation unit 60 having the RDTI structure is used, it is possible to enhance electrical separation between adjacent image plane phase difference pixels by electrically closing the space between the top surface of the insulating film 63b and the P-type semiconductor region 56 with the diffusion region 68c. Note that the dopant included in the diffusion region 68c may be the same as that in a diffusion region 63a. In addition, the diffusion region 68c and the diffusion region 63a may be formed by the same ion implantation step or may be formed in separate ion implantation steps.

### 3.3.4 Fourth Modification

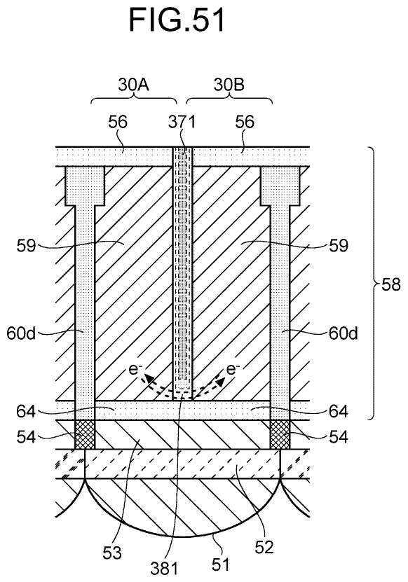

FIG. 51 is a vertical cross-sectional view illustrating a cross-sectional structure example of an image plane phase difference pixel according to a fourth modification. As illustrated in FIG. 51, in the fourth modification, the pixel separation unit 60 having a physical structure is replaced with a diffusion region 60d formed by implanting an ion having a polarity opposite to the charge generated in the photoelectric conversion unit PD into the semiconductor substrate 58. As described above, the separation structure between the image plane phase difference pixel regions (and a portion between the pixel regions) is not limited to a physical structure and may be modified in various manners such as a separation structure by a potential structure.

### 3.3.5 Fifth Modification

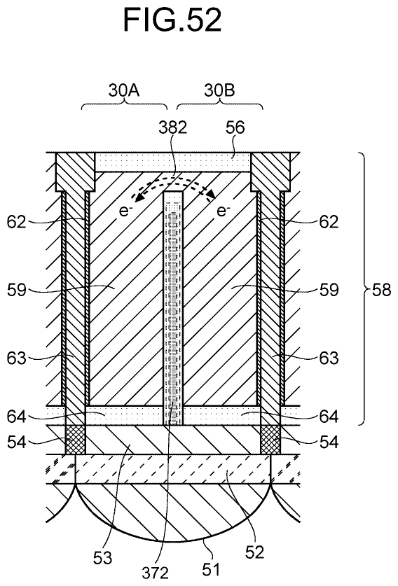

FIG. 52 is a vertical cross-sectional view illustrating a cross-sectional structure example of an image plane phase difference pixel according to a fifth modification. As illustrated in FIG. 52, in the fifth modification, at least the second separation unit 371 in the in-pixel separation unit 370 that divides the image plane phase difference pixel regions partitioned by the pixel separation unit 60 is replaced with a second separation unit 372 having an RDTI structure. In this case, an overflow path 382 is formed on the front surface side (element formation surface side) of the semiconductor substrate 58. As described above, the second separation unit 372 that partitions adjacent pixels despite the overflow path included therein is not limited to the FTI structure but can be modified in various manners. In other words, the formation position of the overflow path is not limited to the back surface side of the semiconductor substrate 58, and various modifications can be made such as the front surface side or the middle portion of the semiconductor substrate 58. Note that the second separation unit 372 having the RDTI structure can be formed, for example, by forming a graded-epi layer from the back surface side of the semiconductor substrate 58 using a film forming method such as graded epitaxial technique capable of controlling the impurity concentration in a stepwise manner.

### 3.3.6 Sixth Modification

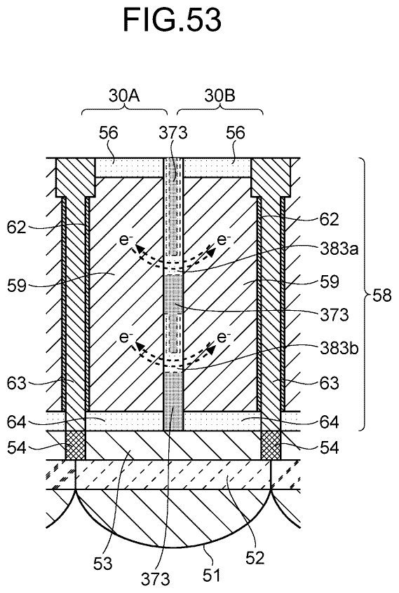

FIG. 53 is a vertical cross-sectional view illustrating a cross-sectional structure example of an image plane phase difference pixel according to a sixth modification. As illustrated in FIG. 53, in the sixth modification, a plurality of overflow paths connecting adjacent pixels is included. Illustrated in FIG. 53 is a case where overflow paths 383a and 383b are formed at two places in the thickness direction of the semiconductor substrate 58. In this manner, the number of overflow paths through which the charge overflowing from one pixel 30 flows is not limited to one, and a plurality of overflow paths may be included. As a result, the charge overflowing from one pixel 30 flows into the other pixel 30 efficiently, and thus it is possible to further reduce the difference in the light receiving sensitivity between the pixels. Note that the position where the plurality of overflow paths 383a and 383b is formed is not limited to the middle portion of the semiconductor substrate 58 and may be the front surface side or the back surface side. In addition, second separation unit 373 including the plurality of overflow paths 383a and 383b may be formed, for example, by executing film forming steps using a film forming method such as the graded epitaxial technique capable of controlling the impurity concentration in a stepwise manner in a plurality of stages.

### 3.3.7 Seventh Modification

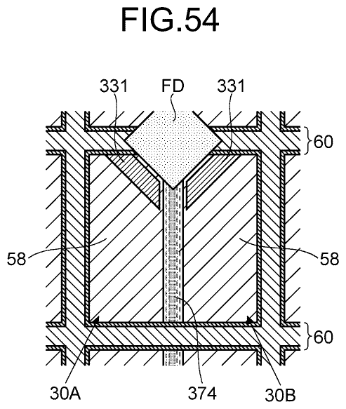

FIG. 54 is a vertical cross-sectional view illustrating a cross-sectional structure example of an image plane phase difference pixel according to a seventh modification. As illustrated in FIG. 54, in the seventh modification, the in-pixel separation unit 370 including the first separation unit 360, the second separation unit 371, and the like is replaced with an in-pixel separation unit 374 entirely including a graded-epi layer. That is, in the present modification, a case where at least one of an upper layer portion, a lower layer portion, and a middle portion of the in-pixel separation unit 374 functions as an overflow path as a whole along the element formation surface of the semiconductor substrate 58 is described as an example. By increasing the width of the overflow path in this manner, the charge overflowing from one pixel 30 flows into the other pixel 30 efficiently, and thus it is possible to further reduce the difference in the light receiving sensitivity between the pixels.

### 3.3.8 Eighth Modification

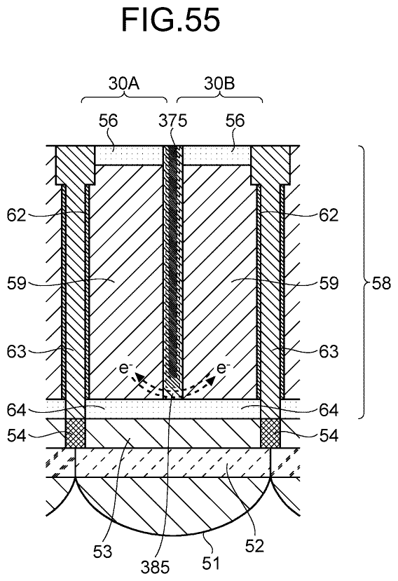

FIG. 55 is a vertical cross-sectional view illustrating a cross-sectional structure example of an image plane phase difference pixel according to an eighth modification. As illustrated in FIG. 55, in the eighth modification, the second separation unit 371 in the in-pixel separation unit 370 is replaced with a second separation unit 375 that electrically separates adjacent pixels using a difference (band offset) in energy level of electrons between substances. The band offset of the second separation unit 371 can be implemented by, for example, a doping density of the impurity, a material composition, or the like. Even in the case where adjacent pixels are electrically separated using the band offset in this manner, it is possible to reduce the difference in the light receiving sensitivity between adjacent pixels by configuring a part of the second separation unit 375 to function as an overflow path 385.

Note that the structure example of the image plane phase difference pixels described as an example in the third embodiment and the structure examples of the image plane phase difference pixels described as an example in the first to eighth modifications can be combined as appropriate. For example, by combining one or more of the structure examples of the image plane phase difference pixels described as an example in the fifth to eighth modifications with the structure example of the image plane phase difference pixel described as an example in the third embodiment or the structure examples of the image plane phase difference pixels described as an example in the first to fourth modifications, it is possible to achieve the effects of each of the structure examples used in the combination.

### 3.4 Summary

As described above, according to the present embodiment, since at least a part of the in-pixel separation unit 370 is constituted by a film (for example, the graded-epi layer) in which the impurity concentration is adjusted such that the opposite polarity is stronger as it is closer to the inner side, it is possible to reduce noise caused by a defect in the vicinity of the separation region as compared with the case of in-pixel separation by a diffusion region. In addition, by adopting the physical separation structure, the width in the horizontal direction of the in-pixel separation is easily controlled, and thus it is possible to suppress a decrease and variation in the saturation signal amount Qs. Furthermore, since the overflow path 371 and the like can be separated away from the transfer transistors 31, the impurity concentration in a portion close to the transfer transistor 31 can be suppressed to be low, and thus deterioration of transfer efficiency and increased noise due to miniaturization can be suppressed. Furthermore, since the in-pixel separation unit 370 is formed of a semiconductor, kicking of incident light and reduction of the photoelectric conversion region can be suppressed.

Other configurations, operations, manufacturing method, and effects may be similar to those of the above-described embodiment, and thus detailed description is omitted here.

### 4. Application Example to Smartphone

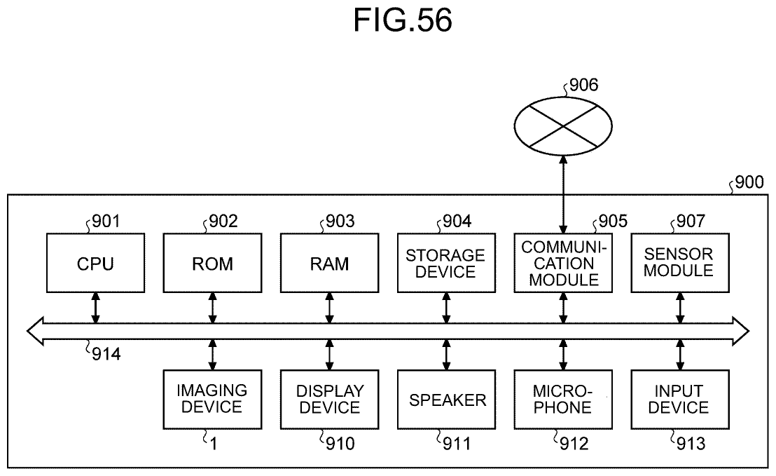

The technology according to the present disclosure (present technology) can be further applied to various products. For example, the technology according to the present disclosure may be applied to a smartphone or the like. Therefore, a configuration example of a smartphone 900 as an electronic apparatus to which the present technology is applied will be described with reference to FIG. 56. FIG. 56 is a block diagram illustrating an example of a schematic functional configuration of the smartphone 900 to which the technology according to the present disclosure (present technology) can be applied.

As illustrated in FIG. 56, the smartphone 900 includes a central processing unit (CPU) 901, a read only memory (ROM) 902, and a random access memory (RAM) 903. The smartphone 900 further includes a storage device 904, a communication module 905, and a sensor module 907. Furthermore, the smartphone 900 includes an imaging device 1, a display device 910, a speaker 911, a microphone 912, an input device 913, and a bus 914. Furthermore, the smartphone 900 may include a processing circuit such as a digital signal processor (DSP) instead of or in addition to the CPU 901.

The CPU 901 functions as an arithmetic processing device and a control device and controls the overall operation in the smartphone 900 or a part thereof in accordance with various programs recorded in the ROM 902, the RAM 903, the storage device 904, or the like. The ROM 902 stores programs, operation parameters, and the like used by the CPU 901. The RAM 903 primarily stores programs used in execution by the CPU 901, parameters that vary as appropriate in the execution, and the like. The CPU 901, the ROM 902, and the RAM 903 are connected to each other by the bus 914. In addition, the storage device 904 is a device for data storage configured as an example of a storage unit of the smartphone 900. The storage device 904 includes, for example, a magnetic storage device such as a hard disk drive (HDD), a semiconductor storage device, an optical storage device, and the like. The storage device 904 stores programs and various types of data executed by the CPU 901, various types of data acquired from the outside, and the like.

The communication module 905 is a communication interface including, for example, a communication device for connection with a communication network 906. The communication module 905 can be, for example, a communication card for wired or wireless local area network (LAN), Bluetooth (registered trademark), wireless USB (WUSB) or the like. Furthermore, the communication module 905 may be a router for optical communication, a router for asymmetric digital subscriber line (ADSL), a modem for various types of communication, or the like. The communication module 905 transmits and receives signals and the like to and from the Internet or other communication devices using a predetermined protocol such as Transmission Control Protocol/Internet Protocol (TCP/IP). Furthermore, the communication network 906 connected to the communication module 905 is a network connected in a wired or wireless manner and is, for example, the Internet, a home LAN, infrared communication, satellite communication, or the like.

The sensor module 907 includes various sensors such as a motion sensor (for example, an acceleration sensor, a gyro sensor, a geomagnetic sensor, or the like), a biological information sensor (for example, a pulse sensor, a blood pressure sensor, a fingerprint sensor, and the like), or a position sensor (for example, a global navigation satellite system (GNSS) receiver or the like).

The imaging device 1 is included on a surface of the smartphone 900 and can capture an image of an object or the like located on the back side or the front side of the smartphone 900. Specifically, the imaging device 1 can include an imaging element (not illustrated) such as a complementary MOS (CMOS) image sensor to which the technology (present technology) according to the present disclosure can be applied and a signal processing circuit (not illustrated) that performs imaging signal processing on a signal photoelectrically converted by the imaging element. Furthermore, the imaging device 1 can further include an optical system mechanism (not illustrated) including an imaging lens, a zoom lens, a focus lens, and the like and a drive system mechanism (not illustrated) that controls the operation of the optical system mechanism. The imaging element can collect incident light from an object as an optical image, and the signal processing circuit can acquire a captured image by photoelectrically converting the formed optical image for each pixel, reading a signal of each pixel as an imaging signal, and performing image processing.

The display device 910 is provided on a surface of the smartphone 900 and can be a display device such as a liquid crystal display (LCD) or an organic electro luminescence (EL) display. The display device 910 can display an operation screen, a captured image acquired by the above-described imaging device 1, and others.

The speaker 911 can output, for example, a call voice, a voice accompanying video content displayed by the display device 910 described above, and the like to the user.

The microphone 912 can collect, for example, a call voice of the user, a voice including a command to activate a function of the smartphone 900, and a voice in a surrounding environment of the smartphone 900.

The input device 913 is a device operated by the user, such as a button, a keyboard, a touch panel, or a mouse. The input device 913 includes an input control circuit that generates an input signal on the basis of information input by the user and outputs the input signal to the CPU 901. By operating the input device 913, the user can input various types of data to the smartphone 900 or give an instruction on a processing operation.

The configuration example of the smartphone 900 has been described above. Each of the above components may be configured using a general-purpose member or may be configured by hardware specialized in the function of each component. Such a configuration can be modified as appropriate depending on the technical level at the time of implementation.

### 5. Application Example to Mobile Body

The technology according to the present disclosure (present technology) can be applied to various products. For example, the technology according to the present disclosure may be implemented as a device to be mounted on a mobile body of any type such as automobiles, electric vehicles, hybrid electric vehicles, motorcycles, bicycles, personal mobility vehicles, airplanes, drones, ships, or robots.

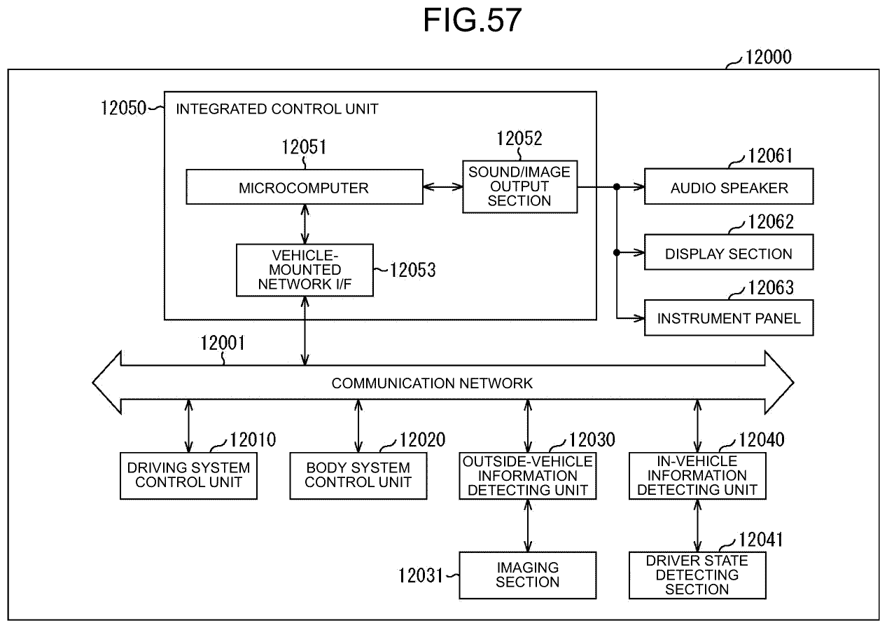

FIG. 57 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 57, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 57, an audio speaker 12061, a display section 12062, and an instrument panel 12063 are illustrated as the output device. The display section 12062 may, for example, include at least one of an on-board display and a head-up display.

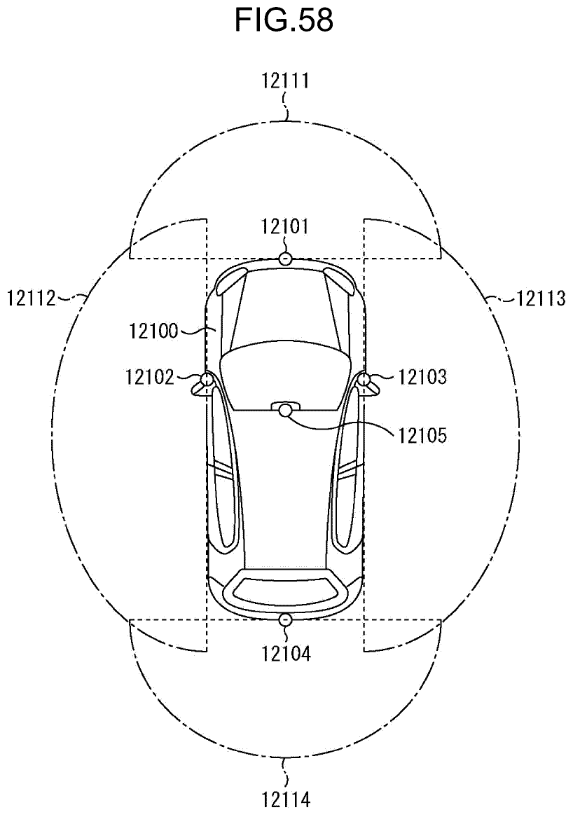

FIG. 58 is a diagram depicting an example of the installation position of the imaging section 12031.

In FIG. 58, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 58 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 in the above-described configuration. By applying the technology according to the present disclosure to the imaging section 12031, a more easily viewable captured image can be obtained, and thus driver's fatigue can be reduced.

### 6. Application Example to Endoscopic Surgery System

The technology according to the present disclosure (present technology) can be applied to various products. For example, the technology according to the present disclosure may be applied to an endoscopic surgery system.

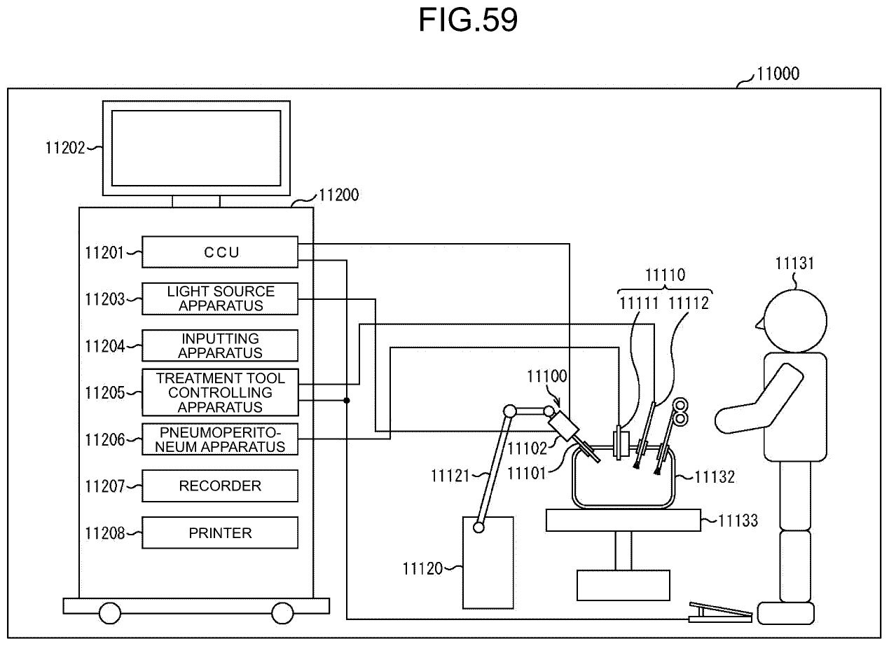

FIG. 59 is a view depicting an example of a schematic configuration of an endoscopic surgery system to which the technology according to an embodiment of the present disclosure (present technology) can be applied.

In FIG. 59, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

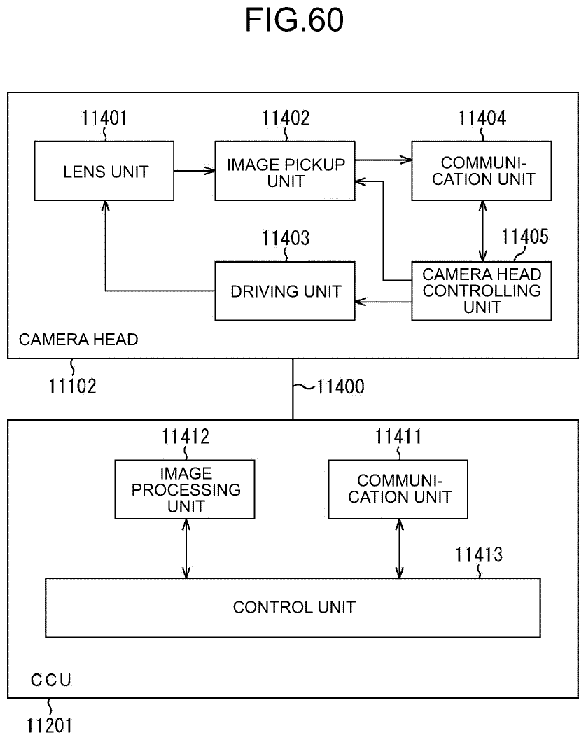

FIG. 60 is a block diagram depicting an example of a functional configuration of the camera head 11102 and the CCU 11201 depicted in FIG. 59.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to, for example, the image pickup unit 11402 of the camera head 11102 among the above-described components. By applying the technology according to the present disclosure to the camera head 11102, a clearer image of the operation site can be obtained, whereby the operator can reliably confirm the surgical region.

Note that, in this example, the endoscopic surgery system has been described as an example, however, the technology according to the present disclosure may be applied to other systems such as a microscopic surgery system.

Although the embodiments of the disclosure have been described above, the technical scope of the disclosure is not limited to the above embodiments as they are, and various modifications can be made without departing from the gist of the disclosure. In addition, components of different embodiments and modifications may be combined as appropriate.

Furthermore, the effects of the embodiments described herein are merely examples and are not limiting, and other effects may be achieved.

Note that the present technology can also have the following configurations.

(1) A solid state imaging device comprising:
a pixel separation unit that partitions a first surface of a semiconductor substrate into a plurality of first regions arrayed in a matrix shape;
an in-pixel separation unit that divides each of the first regions into at least two second regions;
an etching stopper region disposed in at least a partial space between the pixel separation unit and the in-pixel separation unit in a plane parallel to the first surface and in a direction perpendicular to a direction in which the at least two second regions divided by the in-pixel separation unit are arrayed;
a photoelectric conversion unit disposed in each of the second regions; and
a transfer transistor connected to each of the photoelectric conversion units.
   (2) The solid state imaging device according to (1), wherein
the etching stopper region is made of a material in which etch selectivity to a constituent material of the in-pixel separation unit is secured.
   (3) The solid state imaging device according to (1) or (2), wherein
the etching stopper region is a partial region of the semiconductor substrate.
   (4) The solid state imaging device according to any one of (1) to (3), wherein
the in-pixel separation unit extends from the first surface of the semiconductor substrate toward a second surface on an opposite side to the first surface, and does not reach the second surface.
   (5) The solid state imaging device according to any one of (1) to (4), wherein
the in-pixel separation unit contains at least one of diamond, diamond-like carbon (DLC), titanium oxide (TiO₂), cerium oxide (CeO₂), iron oxide (Fe₂O₃), silicon nitride (SiN), gallium arsenide (GaAs), gallium phosphide (GaP), aluminum arsenide (AlAs), aluminum antimonide (AlSb), indium phosphide (InP), hexagonal silicon carbide (4H-SiC), hexagonal silicon carbide (6H-SiC), cubic silicon carbide (3C-SiC), zinc selenide (ZnSe), aluminum antimonide arsenide (AlSbAs), aluminum antimonide phosphide (AlSbP), indium aluminum phosphide (AlInP), gallium arsenide phosphide (GaAsP), indium gallium phosphide (InGaP), and aluminum gallium arsenide (GaAlAs).
   (6) The solid state imaging device according to any one of (1) to (5), wherein
the pixel separation unit contains at least one of silicon oxide (SiO₂), tungsten (W), and aluminum (Al).
   (7) The solid state imaging device according to any one of (1) to (6), wherein
the in-pixel separation unit has a shape in which a width of a top surface located on a second surface side on an opposite side to the first surface of the semiconductor substrate is narrower than a width of a bottom surface located on the first surface side.
   (8) The solid state imaging device according to any one of (1) to (7), wherein
the pixel separation unit optically and electrically separates the first regions from each other, and
the in-pixel separation unit electrically separates the at least two second regions from each other.
   (9) The solid state imaging device according to any one of (1) to (8), wherein
the pixel separation unit is disposed on a surface in contact with the semiconductor substrate and includes a fixed charge film having negative fixed charge.
   (10) The solid state imaging device according to (9), wherein
the fixed charge film contains at least one of oxides of hafnium, zirconium, aluminum, tantalum, titanium, magnesium, yttrium, and lanthanoids.
   (11) A solid state imaging device comprising:
a pixel separation unit that partitions a first surface of a semiconductor substrate into a plurality of first regions arrayed in a matrix shape;
an in-pixel separation unit that divides each of the first regions into at least two second regions, the in-pixel separation unit including an overflow path region for allowing charge accumulated in one of the at least two second regions to flow into at least another second region;
a photoelectric conversion unit disposed in each of the second regions; and
a transfer transistor connected to each of the photoelectric conversion units, wherein
at least a part of the in-pixel separation unit has an impurity concentration profile adjusted such that a potential barrier becomes higher toward a center of the in-pixel separation unit and that the potential barrier becomes higher as a distance from the overflow path increases in a plane parallel to the first surface.
   (12) The solid state imaging device according to (11), wherein
the overflow path region has an impurity concentration profile adjusted to be substantially uniform both in the plane parallel to the first surface and in a plane perpendicular to the first surface.
   (13) The solid state imaging device according to (11) or (12), wherein
at least a part of the in-pixel separation unit is an epitaxial film formed using graded epitaxial technique capable of controlling an impurity concentration in a stepwise manner.
   (14) The solid state imaging device according to any one of (11) to (13), wherein
the impurity has a polarity opposite to a polarity of charge generated in the photoelectric conversion unit.
   (15) The solid state imaging device according to any one of (11) to (14), wherein
the impurity has high potential energy with respect to charge generated in the photoelectric conversion unit.
   (16) The solid state imaging device according to any one of (11) to (15), wherein
at least a part of the in-pixel separation unit is a semiconductor layer containing an impurity having a polarity opposite to a polarity of an impurity contained in the semiconductor substrate.
   (17) The solid state imaging device according to any one of (11) to (16), wherein
at least a part of the in-pixel separation unit includes at least one of a group IV semiconductor including at least one of carbon (C), silicon (Si), germanium (Ge), and tin (Sn), and a group III-V semiconductor including at least two of boron (B), aluminum (Al), gallium (Ga), indium (In), nitrogen (N), phosphorus (P), arsenic (As), and antimony (Sb).
   (18) The solid state imaging device according to any one of (11) to (16), wherein
the potential barrier is formed by a band offset.
   (19) The solid state imaging device according to any one of (11) to (18), wherein
at least another part of the in-pixel separation unit has a same layer structure as a layer structure of the pixel separation unit.
   (20) An electronic apparatus comprising:
the solid state imaging device according to any one of (1) to (19); and
a processor that executes predetermined processing on image data output from the solid state imaging device.

### REFERENCE SIGNS LIST

1 ELECTRONIC APPARATUS (IMAGING DEVICE)
10 SOLID STATE IMAGING DEVICE
11 IMAGING LENS
13 PROCESSOR
14 STORAGE UNIT
21 PIXEL ARRAY UNIT
22 VERTICAL DRIVE CIRCUIT
23 COLUMN PROCESSING CIRCUIT
24 HORIZONTAL DRIVE CIRCUIT
25 SYSTEM CONTROL UNIT
26 SIGNAL PROCESSING UNIT
27 DATA STORAGE UNIT
30, 30A, 30B PIXEL
31 TRANSFER TRANSISTOR
32 RESET TRANSISTOR
33 AMPLIFICATION TRANSISTOR
34 SELECTION TRANSISTOR
41 LIGHT RECEIVING CHIP
42 CIRCUIT CHIP
51 ON-CHIP LENS
52 COLOR FILTER
53 PLANARIZATION FILM
54 LIGHT SHIELDING FILM
55, 63, 63A, 63b, 163a INSULATING FILM
56, 64 P-TYPE SEMICONDUCTOR REGION
57 LIGHT RECEIVING SURFACE
58 SEMICONDUCTOR SUBSTRATE
59 N-TYPE SEMICONDUCTOR REGION
60, 161, 162, 163, 164 PIXEL SEPARATION UNIT
60T, T1 to T3 TRENCH
61 GROOVE
62, 62b FIXED CHARGE FILM
60d, 62a, 68c, 133, 333 DIFFUSION REGION
65 WIRING LAYER
66 WIRING
66-1, 66-2 VIA WIRING
67 INSULATING LAYER
67-1 to 67-3 INTERLAYER INSULATING FILM
68-1 to 68-3 WIRING LAYER
101 ETCHING STOPPER REGION
131, 331 GATE ELECTRODE
132, 332 GATE INSULATING FILM
163b, 164b INSULATING FILM (SCF)
164a LIGHT SHIELDING FILM
170, 171, 370, 374 IN-PIXEL SEPARATION UNIT
170A FILM
334 VIA CONTACT
360 FIRST SEPARATION UNIT
371, 372, 373, 375 SECOND SEPARATION UNIT
381, 382, 383a, 383b, 385 OVERFLOW PATH
FD FLOATING DIFFUSION REGION
PD PHOTOELECTRIC CONVERSION UNIT

1. A solid state imaging device comprising:
a pixel separation unit that partitions a first surface of a semiconductor substrate into a plurality of first regions arrayed in a matrix shape;
an in-pixel separation unit that divides each of the first regions into at least two second regions;
an etching stopper region disposed in at least a partial space between the pixel separation unit and the in-pixel separation unit in a plane parallel to the first surface and in a direction perpendicular to a direction in which the at least two second regions divided by the in-pixel separation unit are arrayed;
a photoelectric conversion unit disposed in each of the second regions; and
a transfer transistor connected to each of the photoelectric conversion units.

2. The solid state imaging device according to claim 1, wherein
the etching stopper region is made of a material in which etch selectivity to a constituent material of the in-pixel separation unit is secured.

3. The solid state imaging device according to claim 1, wherein
the etching stopper region is a partial region of the semiconductor substrate.

4. The solid state imaging device according to claim 1, wherein
the in-pixel separation unit extends from the first surface of the semiconductor substrate toward a second surface on an opposite side to the first surface, and does not reach the second surface.

5. The solid state imaging device according to claim 1, wherein
the in-pixel separation unit contains at least one of diamond, diamond-like carbon (DLC), titanium oxide (TiO₂), cerium oxide (CeO₂), iron oxide (Fe₂O₃), silicon nitride (SiN), gallium arsenide (GaAs), gallium phosphide (GaP), aluminum arsenide (AlAs), aluminum antimonide (AlSb), indium phosphide (InP), hexagonal silicon carbide (4H-SiC), hexagonal silicon carbide (6H-SiC), cubic silicon carbide (3C-SiC), zinc selenide (ZnSe), aluminum antimonide arsenide (AlSbAs), aluminum antimonide phosphide (AlSbP), indium aluminum phosphide (AlInP), gallium arsenide phosphide (GaAsP), indium gallium phosphide (InGaP), and aluminum gallium arsenide (GaAlAs).

6. The solid state imaging device according to claim 1, wherein
the pixel separation unit contains at least one of silicon oxide (SiO₂), tungsten (W), and aluminum (Al).

7. The solid state imaging device according to claim 1, wherein
the in-pixel separation unit has a shape in which a width of a top surface located on a second surface side on an opposite side to the first surface of the semiconductor substrate is narrower than a width of a bottom surface located on the first surface side.

8. The solid state imaging device according to claim 1, wherein
the pixel separation unit optically and electrically separates the first regions from each other, and
the in-pixel separation unit electrically separates the at least two second regions from each other.

9. The solid state imaging device according to claim 1, wherein
the pixel separation unit is disposed on a surface in contact with the semiconductor substrate and includes a fixed charge film having negative fixed charge.

10. The solid state imaging device according to claim 9, wherein
the fixed charge film contains at least one of oxides of hafnium, zirconium, aluminum, tantalum, titanium, magnesium, yttrium, and lanthanoids.

11. A solid state imaging device comprising:
a pixel separation unit that partitions a first surface of a semiconductor substrate into a plurality of first regions arrayed in a matrix shape;
an in-pixel separation unit that divides each of the first regions into at least two second regions, the in-pixel separation unit including an overflow path region for allowing charge accumulated in one of the at least two second regions to flow into at least another second region;
a photoelectric conversion unit disposed in each of the second regions; and
a transfer transistor connected to each of the photoelectric conversion units, wherein
at least a part of the in-pixel separation unit has an impurity concentration profile adjusted such that a potential barrier becomes higher toward a center of the in-pixel separation unit and that the potential barrier becomes higher as a distance from the overflow path increases in a plane parallel to the first surface.

12. The solid state imaging device according to claim 11, wherein
the overflow path region has an impurity concentration profile adjusted to be substantially uniform both in the plane parallel to the first surface and in a plane perpendicular to the first surface.

13. The solid state imaging device according to claim 11, wherein
at least a part of the in-pixel separation unit is an epitaxial film formed using graded epitaxial technique capable of controlling an impurity concentration in a stepwise manner.

14. The solid state imaging device according to claim 11, wherein
the impurity has a polarity opposite to a polarity of charge generated in the photoelectric conversion unit.

15. The solid state imaging device according to claim 11, wherein
the impurity has high potential energy with respect to charge generated in the photoelectric conversion unit.

16. The solid state imaging device according to claim 11, wherein
at least a part of the in-pixel separation unit is a semiconductor layer containing an impurity having a polarity opposite to a polarity of an impurity contained in the semiconductor substrate.

17. The solid state imaging device according to claim 11, wherein
at least a part of the in-pixel separation unit includes at least one of a group IV semiconductor including at least one of carbon (C), silicon (Si), germanium (Ge), and tin (Sn), and a group III-V semiconductor including at least two of boron (B), aluminum (Al), gallium (Ga), indium (In), nitrogen (N), phosphorus (P), arsenic (As), and antimony (Sb).

18. The solid state imaging device according to claim 11, wherein
the potential barrier is formed by a band offset.

19. The solid state imaging device according to claim 11, wherein
at least another part of the in-pixel separation unit has a same layer structure as a layer structure of the pixel separation unit.

20. An electronic apparatus comprising:
the solid state imaging device according to claim 1; and
a processor that executes predetermined processing on image data output from the solid state imaging device.
